(19) United States
(12) Patent Application Publication
(10) Pub. No.: US 2026/0182003 A1
(43) Pub. Date: Jun. 25, 2026

(54) PROTECTION LAYER FOR STACKED MULTI-GATE DEVICE FORMATION

(71) Applicant: Taiwan Semiconductor Manufacturing Company, Ltd., Hsin-Chu (TW)

(72) Inventors: Hung-Kun Lo, New Taipei City (TW); Jin-Hao Jhang, Chubei City (TW); Ku-Feng Yang, Baoshan Township (TW); Szuya Liao, Zhubei Hsinchu (TW)

(21) Appl. No.: 19/183,199

(22) Filed: Apr. 18, 2025

Related U.S. Application Data
(60) Provisional application No. 63/736,056, filed on Dec. 19, 2024.

(51) Int. Cl. H10D 84/01; H10D 30/00; H10D 30/01; H10D 30/43; H10D 62/10; H10D 84/85

(52) U.S. Cl. CPC H10D 84/0181; H10D 30/014; H10D 30/0191; H10D 62/121; H10D 84/0172; H10D 30/43; H10D 30/502; H10D 84/851

(57) ABSTRACT

Semiconductor devices and methods of forming the same are provided. An exemplary method includes forming a bottom nanostructure and a top nanostructure over a substrate, forming a first gate dielectric layer around the bottom nanostructure and a second gate dielectric layer around the top nanostructure, sequentially depositing a dipole layer, a pattern layer, a self-assembled monolayer (SAM), and a dummy layer on the first and second gate dielectric layers, planarizing the dummy layer, removing portions of the SAM, the dummy layer, the dipole layer and the pattern layer over the second gate dielectric layer, removing remaining portions of the SAM, the dummy layer, and the pattern layer, thereby leaving a portion of the dipole layer on the first gate dielectric layer, and performing a treatment to drive a dipole dopant species from the portion of the dipole layer to the first gate dielectric layer.

### PRIORITY DATA

The present application claims the benefit of U.S. Provisional Application No. 63/736,056, filed Dec. 19, 2024, which is herein incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs. For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanosheet transistor or a nanowire transistor.

As the semiconductor industry further progresses in pursuit of higher device density, higher performance, and lower costs, challenges from both fabrication and design issues have led to stacked device structure configurations, such as complementary field effect transistors (C-FETs) where an n-type multi-gate transistor and a p-type multi-gate transistor are stacked vertically, one over the other.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a perspective view of a semiconductor device including a vertical C-FET, according to one or more aspects of the present disclosure.

FIG. 2 illustrates a flow chart of a method for forming a semiconductor device including a vertical C-FET, according to one or more aspects of the present disclosure.

FIGS. 3, 4, 5, 6, 7, 8, 9, 10, 11, 12, 13, 14, 20, 21, 22, 23, 24, 25, 26, 27, 28, and 29 illustrate fragmentary cross-sectional views of the semiconductor device during various fabrication stages in the method of FIG. 2, according to various aspects of the present disclosure.

FIG. 15 illustrates exemplary acid head groups of precursors for forming a first type self-assembled monolayer (SAM) during the fabrication stages in the method of FIG. 2, according to various aspects of the present disclosure.

FIGS. 15A, 15B, 15C, 15D, 16A, 16B, 16C, 16D, 16E, 16F, 16G, 16H, 17A, 17B, 18A, and 18B represent various aspects of the first type SAM that can be applied during the fabrication stages in the method of FIG. 2, according to various embodiments of the present disclosure.

FIGS. 19A, 19B, 19C, 19D represent various aspects of a second type SAM that can be applied during the fabrication stages in the method of FIG. 2, according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Stacked transistor structures can provide further density reduction for advanced integrated circuit (IC) technology nodes (particularly as they advance to 3 nm (N3) and below), especially when the stacked transistor structures include multi-gate devices, such as fin-like field effect transistors (FinFETs), gate-all-around (GAA) transistors including nanowires and/or nanosheets, other types of multi-gate devices, etc. A stacked transistor structure can include a first transistor (e.g., an upper transistor) disposed over a second transistor (e.g., a lower transistor). The stacked transistor structure can provide a complementary field effect transistor (C-FET) when the first transistor and the second transistor are of opposite conductivity type (i.e., an n-type transistor and a p-type transistor).

An IC may include numerous stacked transistor structures. Providing the IC with transistors having multiple threshold voltages (Vt) can maximize its performance and/or reliability, for example, by boosting performance/speed of some transistors of the IC while reducing power consumption of other transistors of the IC. However, providing multi-gate devices with multiple threshold voltages is challenging because multi-gate devices are becoming very small, which leaves minimal room for tuning their threshold voltages using different work function metals. Dipole engineering can flexibly provide multi-gate devices with different threshold voltages by incorporating dipole dopants into gate dielectric layers thereof and minimize and/or eliminate the need for using different work function metals.

The present disclosure provides a method of implementing dipole engineering to flexibly adjust threshold voltages of transistors in a stacked transistor structure (e.g., a C-FET). A dipole layer may be conformally formed over a gate dielectric layer. Multiple material layers may be formed over the dipole layer to facilitate the patterning of the dipole layer such that the patterned dipole layer may act as a dipole diffusion source for either a portion of the gate dielectric layer for a lower transistor or a portion of the gate dielectric layer for an upper transistor. During a planarization process, one layer (e.g., a barrier layer formed of TiN) may be damaged, and reliability or other aspects of performance of the C-FET may be disadvantageously affected. In this disclosure, a self-assembled monolayer (SAM) is formed on the barrier layer. By forming the SAM, damage to the barrier layer caused by the planarization process may be substantially reduced or even eliminated.

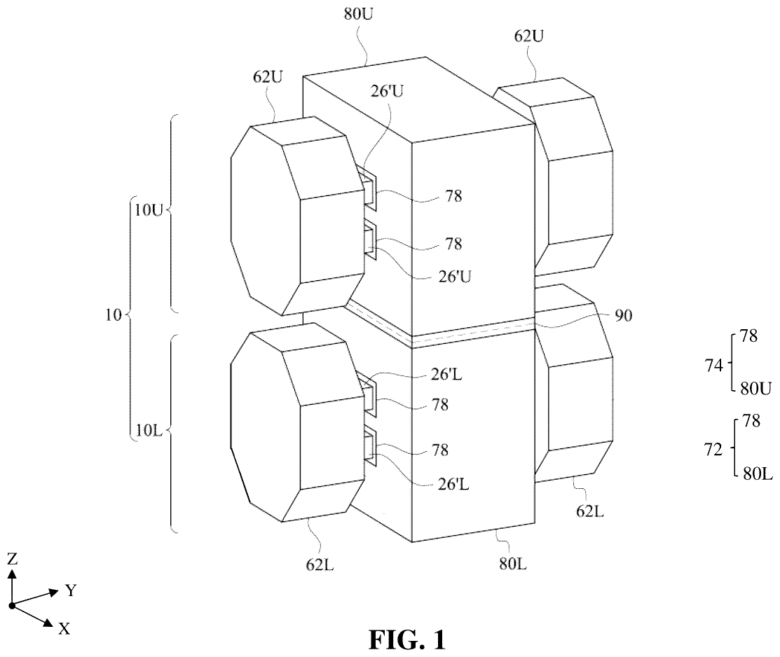

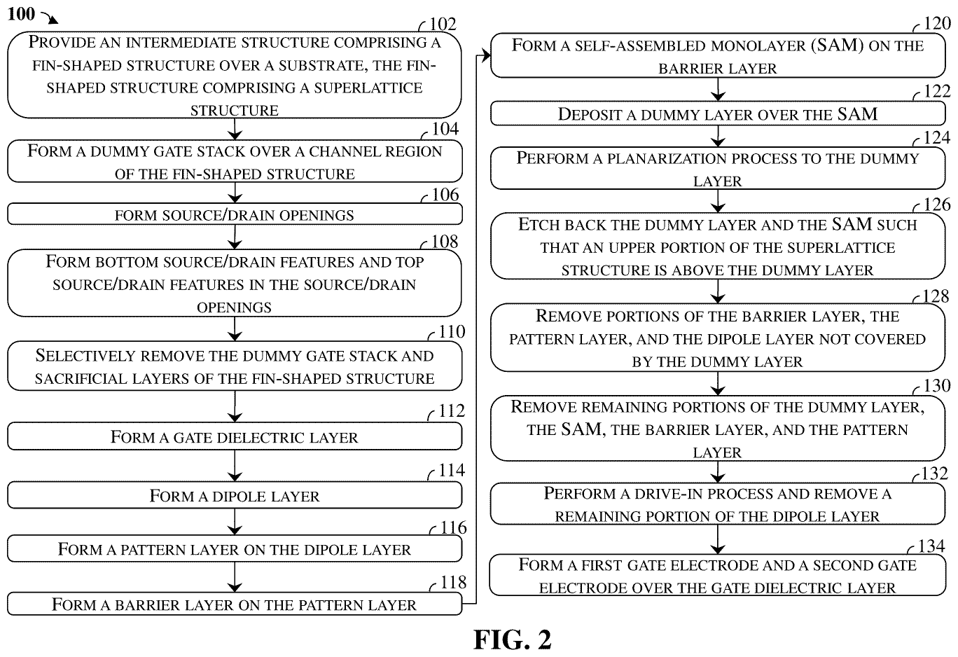

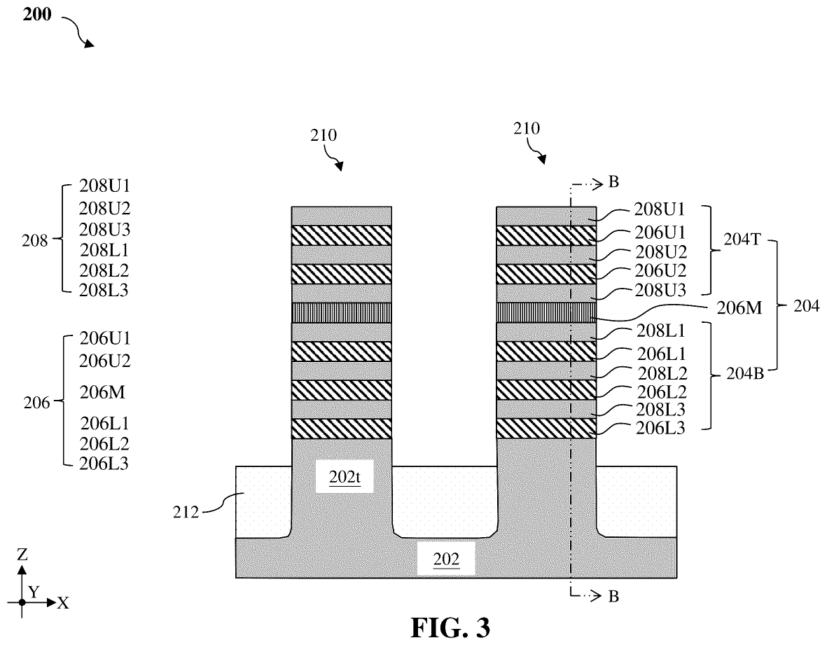

The various aspects of the present disclosure will now be described in more detail with reference to the figures. In that regard, FIG. 1 illustrates a perspective view of a semiconductor device including a vertical C-FET, according to one or more aspects of the present disclosure. FIG. 2 illustrates a flow chart of a method 100 for forming a semiconductor device 200 including a vertical C-FET, according to one or more aspects of the present disclosure. Method 100 is described below in conjunction with FIGS. 3-29, which may include fragmentary cross-sectional views of the intermediate structure 200 at different stages of fabrication according to embodiments of method 100 or exemplary illustration of a self-aligned monolayer (SAM) that is formed during different stages of fabrication according to embodiments of method 100. Method 100 is merely an example and is not intended to limit the present disclosure to what is explicitly illustrated therein. Additional steps may be provided before, during and after method 100, and some steps described can be replaced, eliminated, or moved around for additional embodiments of the method. Not all steps are described herein in detail for reasons of simplicity. Because the intermediate structure 200 will be fabricated into a semiconductor device 200 upon conclusion of the fabrication processes, the intermediate structure 200 may be referred to as the semiconductor device 200 as the context requires. Additionally, throughout the present application and across different embodiments, like reference numerals denote like features with similar structures and compositions, unless otherwise excepted. For avoidance of doubts, the X, Y and Z directions in the figures are perpendicular to one another and are used consistently.

FIG. 1 depicts an exemplary semiconductor device (e.g., C-FET) 10. The semiconductor device 10 includes a lower device 10L (e.g., p-type transistor) and an upper device 10U (e.g., n-type transistor) over the lower device 10L. The upper device 10U includes channel layers 26′U wrapped around by an upper gate structure 74. The upper gate structure 74 includes a gate dielectric layer 78 and a gate electrode 80U. The upper device 10U also includes source/drain features (e.g., n-type epitaxial source/drain features) 62U coupled to the channel layers 26′U and adjacent the upper gate structure 74.

The lower device 10L includes channel layers 26′L wrapped around by a bottom gate structure 72. The bottom gate structure 72 includes a gate dielectric layer 78′ and a gate electrode 80L. In this present disclosure, the gate dielectric layer 78 and the gate dielectric layer 78′ have different compositions. For example, the gate dielectric layer 78′ may include dipole dopant species. The lower device 10L also includes source/drain features (e.g., p-type epitaxial source/drain features) 62L coupled to the channel layers 26′L and adjacent to the bottom gate structure 72.

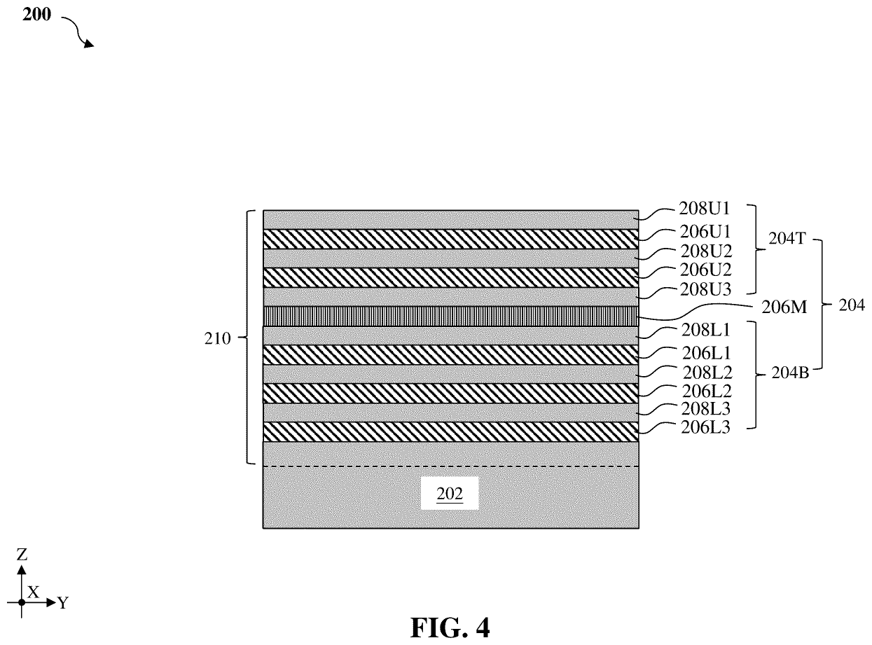

FIG. 2 illustrates a flow chart of a method for forming a semiconductor device 200 including a vertical C-FET, according to one or more aspects of the present disclosure. Referring now to FIGS. 2 and 3-4, method 100 includes a block 102 where an intermediate structure 200 is received. FIG. 3 depicts a cross-sectional view of the intermediate structure 200, and FIG. 4 depicts a fragmentary cross-sectional view of the intermediate structure 200 taken along line B-B shown in FIG. 3. The intermediate structure 200 includes a substrate 202. In one embodiment, the substrate 202 may be a silicon (Si) substrate. In some other embodiments, the substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure. Although not explicitly shown in the figures, the substrate 202 may include an n-type well region and a p-type well region for fabrication of transistors of different conductivity types. When present, each of the n-type well and the p-type well is formed in the substrate 202 and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the substrate 202.

The intermediate structure 200 also includes fin-shaped structures 210 protruding from the substrate 202. In the present embodiments, the fin-shaped structure 210 is formed from a superlattice structure 204 and a portion of the substrate 202. The superlattice structure 204 may be deposited over the substrate 202 using an epitaxy process. Suitable epitaxy processes include vapor-phase epitaxy (VPE), ultra-high vacuum chemical vapor deposition (UHV-CVD), molecular beam epitaxy (MBE), and/or other suitable processes. The superlattice structure 204 includes a number of channel layers 208 interleaved by a number of sacrificial layers 206. The sacrificial layers 206 and the channel layers 208 are deposited alternatingly, one-after-another, to form the superlattice structure 204. The channel layers 208 and the sacrificial layers 206 may have different semiconductor compositions. In some implementations, the channel layers 208 are formed of silicon (Si), and the sacrificial layers 206 are formed of silicon germanium (SiGe). Precursors for forming the channel layers 208 may include silane, dichloride silane, germane, digermane, tetrachloride germane, diborane, boron trichloride, and/or or HCl. In these implementations, the additional germanium content in the sacrificial layers 206 allows selective removal or recess of the sacrificial layers 206 without inducing substantial damages to the channel layers 208.

For ease of references, the superlattice structure 204 may be vertically divided into a bottom portion 204B, a middle sacrificial layer 206M on the bottom portion 204B, and a top portion 204T on the middle sacrificial layer 206M. In this depicted example, the bottom portion 204B of the superlattice structure 204 includes channel layers 208L1, 208L2 and 208L3 interleaved by sacrificial layers 206L1, 206L2, and 206L3. The top portion 204T of the superlattice structure 204 includes channel layers 208U1, 208U2 and 208U3 interleaved by sacrificial layers 206U1 and 206U2. The channel layers 208L1, 208L2, 208L3, 208U1, 208U2, and 208U3 will provide nanostructures for the C-FET. In some embodiments, the channel layers 208U1-208U2 will provide channel members for an upper GAA transistor of the C-FET, and the channel layers 208L2-208L3 will provide channel members for a lower GAA transistor in the C-FET. The term “channel member(s)” is used herein to designate any material portion for channel(s) in a transistor with nanoscale dimensions, and having an elongate shape, regardless of the cross-sectional shape of this portion. A germanium content of the middle sacrificial layer 206M may be different from the germanium content of other sacrificial layers (e.g., sacrificial layers 206U1-206U2, sacrificial layers 206L1-206L3) of the top portion 204T and bottom portion 204B. In some embodiments, a germanium content of the middle sacrificial layer 206M is greater than a germanium content of the other sacrificial layers 206U1-206U2 and 206L1-206L3 such that the entirety of the middle sacrificial layer 206M may be selectively removed during the formation of inner spacer recesses. It is noted that the superlattice structure 204 in FIGS. 3-4 includes six (6) layers of the channel layers 208 interleaved by six (6) layers of sacrificial layers 206, which is for illustrative purposes only and not intended to be limiting beyond what is specifically recited in the claims. It can be appreciated that any number of the channel layers 208 can be included in the superlattice structure 204 and distributed within the bottom portion 204B and the top portion 204T. The number of layers depends on the desired number of channels members for the upper GAA transistor and the lower GAA transistor. In some embodiments, the number of the channel layers 208 in the superlattice structure 204 may be between 4 and 10.

The superlattice structure 204 and a portion of the substrate 202 are then patterned to form the fin-shaped structures 210. The patterned portion of the substrate 202 may be referred to as a protrusion 202t, a mesa 202t, or a base fin 202t. For patterning purposes, a hard mask layer may be deposited over the superlattice structure 204. The hard mask layer may be a single layer or a multilayer. In one example, the hard mask layer includes a silicon oxide layer and a silicon nitride layer over the silicon oxide layer. As shown in FIGS. 3-4, each fin-shaped structure 210 extends vertically along the Z direction from the substrate 202 and extends lengthwise along the Y direction. The fin-shaped structures 210 may be patterned using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used as an etch mask to etch the superlattice structure 204 and the substrate 202 to form the fin-shaped structures 210.

The intermediate structure 200 also includes an isolation feature 212 (shown in FIG. 3) formed around the fin-shaped structures 210 to separate two adjacent fin-shaped structures 210. The isolation feature 212 may also be referred to as a shallow trench isolation (STI) feature 212. In an example process, a dielectric material for the isolation feature 212 is deposited over the intermediate structure 200, including the fin-shaped structure 210, using CVD, sub-atmospheric CVD (SACVD), flowable CVD, spin-on coating, and/or other suitable process. Then, the deposited dielectric material is planarized and recessed to form the isolation feature 212. As shown in FIG. 3, the fin-shaped structure 210 rises above the isolation feature 212. The dielectric material for the isolation feature 212 may include silicon oxide, silicon oxynitride, fluorine-doped silicate glass (FSG), a low-k dielectric, combinations thereof, and/or other suitable materials.

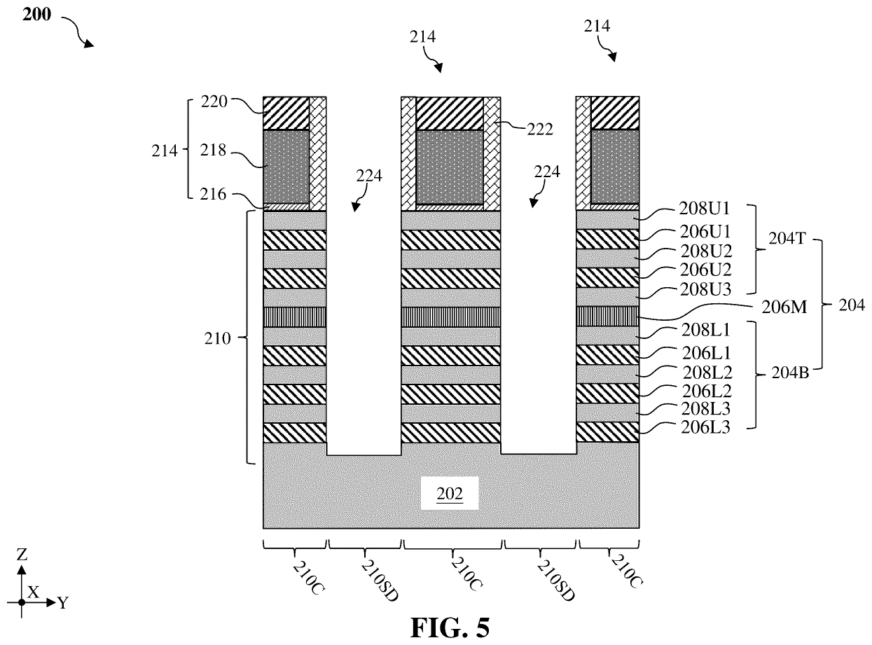

Referring to FIGS. 2 and 5, method 100 includes a block 104 where a dummy gate stack 214 is formed over a channel region 210C of the fin-shaped structure 210. In some embodiments, a gate replacement process (or gate-last process) is adopted where each dummy gate stack 214 serves as a placeholder for a functional gate structure. Other processes and configurations are possible. To form the dummy gate stack 214, a dummy dielectric layer 216, a dummy gate electrode 218, and a gate-top hard mask layer 220 are deposited over the intermediate structure 200. The deposition of these layers may include use of chemical vapor deposition (CVD), low-pressure CVD (LPCVD), plasma-enhanced CVD (PECVD), physical vapor deposition (PVD), atomic layer deposition (ALD), thermal oxidation, e-beam evaporation, other suitable deposition techniques, and/or combinations thereof. The dummy dielectric layer 216 may include silicon oxide, the dummy gate electrode 218 may include polysilicon, and the gate-top hard mask layer 220 may be a multi-layer structure that includes silicon oxide and silicon nitride. Using photolithography and etching processes, the gate-top hard mask layer 220 is patterned. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The etching process may include dry etching, wet etching, and/or other etching methods. Like the fin-shaped structures 210, the dummy gate stack 214 may also be patterned using double-patterning or multiple-patterning techniques. Thereafter, using the patterned gate-top hard mask 220 as an etch mask, the dummy dielectric layer 216 and the dummy gate electrode 218 are then etched to form the dummy gate stacks 214. The portion of the fin-shaped structure 210 underlying the dummy gate stack 214 defines a channel region 210C. The channel region 210C and the dummy gate stack 214 also define source/drain regions 210SD that are not vertically overlapped by the dummy gate stack 214. The channel region 210C is disposed between two source/drain regions 210SD along the Y direction. Source/drain region(s) may refer to a source region for forming a source and/or a drain region for forming a drain, individually or collectively dependent upon the context.

Still referring to FIGS. 2 and 5, method 100 includes a block 106 where source/drain regions 210SD of the fin-shaped structure 210 are recessed to form source/drain openings 224. Operations at block 106 may include formation of gate spacers 222 over the sidewalls of the dummy gate stack 214 before the source/drain regions 210SD are recessed. In some embodiments, the formation of the gate spacers 222 includes deposition of one or more dielectric layers over the intermediate structure 200. In an example process, the one or more dielectric layers are conformally deposited using CVD, SACVD, or ALD. The one or more dielectric layers may include silicon oxide, silicon nitride, silicon carbide, silicon oxynitride, silicon carbonitride, silicon oxycarbide, silicon oxycarbonitride, and/or combinations thereof. In an embodiment, the gate spacer 222 includes silicon oxycarbonitride (SiOCN). After the formation of the gate spacers 222, an etching process is performed to the intermediate structure 200 to form the source/drain openings 224. The etching process at block 106 may be a dry etch process or other suitable etch process. An example dry etching process may implement an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments, the etching process at block 106 does not substantially etch the substrate 202. In some other embodiments, the source/drain openings 224 may extend into the substrate 202. As shown in FIG. 5, sidewalls of the sacrificial layers 206 and the channel layers 208 in the channel regions 210C are exposed in the source/drain openings 224.

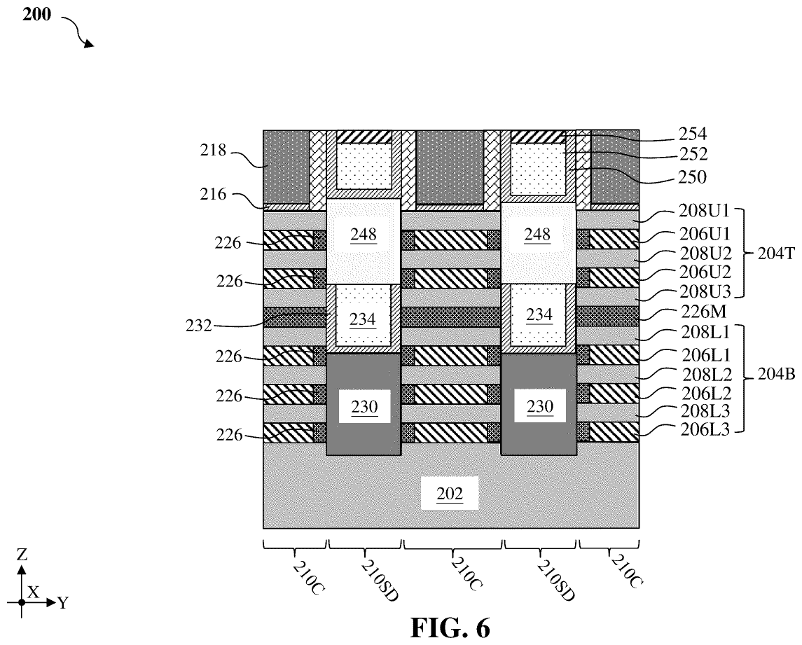

Referring to FIGS. 2 and 6, method 100 includes a block 108 where bottom source/drain features 230 and top source/drain features 248 are formed in the source/drain openings 224. Before forming the bottom source/drain features 230 and top source/drain features 248, inner spacer features 226 are formed. More specifically, after forming the source/drain openings 224, the sacrificial layers 206 exposed in the source/drain openings 224 are selectively and partially recessed to form inner spacer recesses, while the exposed channel layers 208 are substantially unetched. The middle sacrificial layer 206M, due to its greater germanium content, may be substantially removed during the formation of inner spacer recesses. In some embodiments, the selective recess may be a selective isotropic etching process (e.g., a selective dry etching process or a selective wet etching process), and the extent at which the sacrificial layers 206 are recessed is controlled by duration of the etching process. The selective dry etching process may include use of one or more fluorine-based etchants, such as fluorine gas or hydrofluorocarbons. The selective wet etching process may include use of hydrogen fluoride (HF) or ammonium hydroxide (NH₄OH). After the formation of the inner spacer recesses, an inner spacer material layer is deposited over the intermediate structure 200, including in the inner spacer recesses. Additionally, as shown in FIG. 6, the inner spacer material layer may also be deposited in the space left behind by selective removal of the middle sacrificial layer 206M. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excess portions of the inner spacer material layer over the dummy gate stack 214, the gate spacer 222, and sidewalls of the channel layers 208, thereby forming the inner spacer features 226 and a middle dielectric layer 226M as shown in FIG. 6.

After forming the inner spacer features 226 and the middle dielectric layer 226M, bottom source/drain features 230 are formed in the source/drain openings 224. In some embodiments, before the deposition of the bottom source/drain features 230, a blocking layer (not shown) may be deposited over the intermediate structure 200 to cover sidewalls of the top portion 204T of the superlattice structure 204. The blocking layer may also cover sidewalls of the middle dielectric layer 226M and the channel layer 208L1. The blocking layer may include dielectric materials. After the formation of the blocking layer, the bottom source/drain features 230 may be formed using an epitaxial process, such as VPE, UHV-CVD, MBE, and/or other suitable processes. The epitaxial growth process may use gaseous and/or liquid precursors, which interact with the composition of the substrate 202 as well as the channel layers 208 not covered by the blocking layer. In the present embodiments, the epitaxial growth of bottom source/drain features 230 may take place from both the top surface of the substrate 202 and the exposed sidewalls of the channel layers 208L2 and 208L3. The blocking layer, due to its dielectric composition, blocks formation of the bottom source/drain features 230 on sidewalls of the channel layers 208U1-208U3 and 208L1. As illustrated in FIG. 6, the bottom source/drain features 230 are in physical contact with (or adjoining) the channel layers 208L2 and 208L3. Depending on the design, the bottom source/drain features 230 may be n-type or p-type. In the depicted embodiments, the bottom source/drain features 230 are p-type source/drain features and may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process.

Operations at block 108 also include forming a bottom contact etch stop layer (CESL) 232 and a bottom interlayer dielectric (ILD) layer 234 over the bottom source/drain features 230. The bottom CESL 232 may include silicon nitride, silicon oxynitride, and/or other materials and may be formed by CVD, ALD, plasma-enhanced chemical vapor deposition (PECVD) process and/or other suitable deposition or oxidation processes. The bottom ILD layer 234 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials and may be formed by spin-on coating, flowable CVD (FCVD), CVD, or other suitable deposition technique. In an exemplary process, the bottom CESL 232 is first conformally deposited on the intermediate structure 200 and the bottom ILD layer 234 is deposited over the bottom CESL 232. After depositing, the bottom CESL 232 and the bottom ILD layer 234 are etched back to exposed sidewalls of the channel layers 208U1 and 208U2. The blocking layer may be removed during and/or after the etch back of the bottom CESL 232 and the bottom ILD layer 234.

After forming the bottom CESL 232 and the bottom ILD layer 234, top source/drain features 248 are formed over the bottom CESL 232 and the bottom ILD layer 234. The top source/drain features 248 may be formed using an epitaxial process, such as VPE, UHV-CVD, MBE, and/or other suitable processes. The epitaxial growth process may use gaseous and/or liquid precursors, which interact with composition of the channel layers (e.g., channel layers 208U1 and 208U2) of the top portion 204T of the superlattice structure 204. The epitaxial growth of top source/drain features 248 may take place from the exposed sidewalls of the upper channel layers 208U1 and 208U2. The deposited top source/drain features 248 are in physical contact with (or adjoining) the channel layers of the top portion 204T of the superlattice structure 204. Depending on the design, the top source/drain features 248 may be n-type or p-type. In the depicted embodiments, the top source/drain features 248 are n-type source/drain features and may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process.

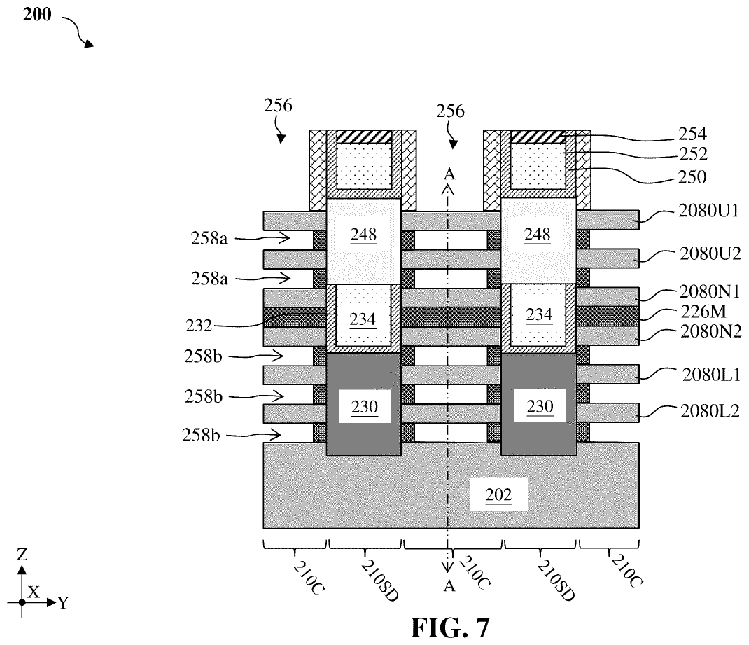

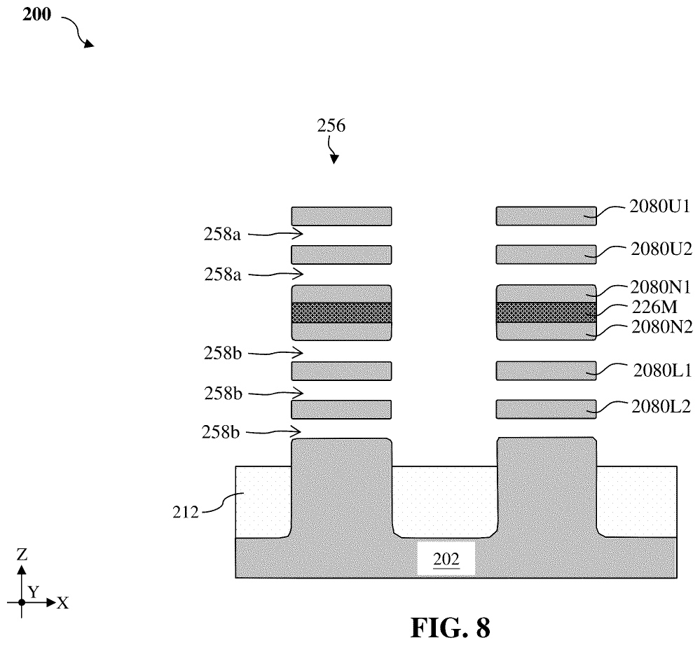

Referring to FIGS. 2 and 6-8, method 100 includes a block 110 where the dummy gate stacks 214 and sacrificial layers 206 of the fin-shaped structures 210 are removed. FIG. 8 depicts a cross-sectional view of the intermediate structure 200 taken along line A-A shown in FIG. 7. After forming the top source/drain features 248, a top CESL 250 and a top ILD layer 252 are deposited over the top source/drain features 248. The top CESL 250 may include silicon nitride, silicon oxynitride, and/or other materials known in the art and may be formed by CVD, ALD, plasma-enhanced chemical vapor deposition (PECVD) process and/or other suitable deposition or oxidation processes. In some embodiments, the top CESL 250 is first conformally deposited on the intermediate structure 200, and the top ILD layer 252 is then deposited over the top CESL 250 by spin-on coating, FCVD, CVD, or other suitable deposition technique. The top ILD layer 252 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the top ILD layer 252, the intermediate structure 200 may be annealed to improve integrity of the top ILD layer 252. A planarization process, such a chemical mechanical polishing (CMP) process may be performed to remove excess materials (e.g., the gate-top hard mask layer 220) to expose the top surface of the dummy gate electrode 218. Top surfaces of the top CESL 250 and top ILD layer 252 are coplanar with the top surface of the dummy gate electrode 218.

With reference to FIG. 6, operations at block 110 may also include forming a hard mask 254 on the top ILD layer 252. In an exemplary process, a suitable etching process is performed to remove top portions of the top ILD layer 252 to form trenches between the dummy gate stacks 214. The etching process may be implemented to selectively remove the top portions of the top ILD layer 252 without removing, or substantially removing, the dummy gate stacks 214, top CESL 250, or the gate spacers 222. The etching process may be a dry etching process, a wet etching process, an RIE process, other suitable processes, or combinations thereof. Then, the hard mask 254 is formed over the recessed top ILD layer 252, thereby filling the trenches. The hard mask 254 may include silicon oxide, SiN, SiCN, SiOC, SiON, SiOCN, other suitable materials, or combinations thereof, and may be formed by a combination of deposition process (e.g., CVD, ALD, PVD, other suitable methods, or combinations thereof) and a planarization process (e.g., chemical mechanical polishing (CMP)). In the present embodiments, the hard mask 254 includes SiN. As represented by FIG. 6, the hard mask 254 is disposed between but not over the top surfaces of the dummy gate stacks 214.

With reference to FIGS. 7-8, with the exposure of the dummy gate electrodes 218 and the formation of the hard mask 254, an etching process is performed to selectively remove the dummy gate stacks 214. The removal of the dummy gate stacks 214 may include one or more etching processes that are selective to the material in the dummy gate stacks 214. For example, the removal of the dummy gate stacks 214 may be performed using as a selective wet etch, a selective dry etch, or a combination thereof. The removal of the dummy gate stacks 214 forms gate trenches 256.

After the removal of the dummy gate stacks 214, sidewalls of the channel layers 208 and sacrificial layers 206 in the channel regions 210C are exposed. Thereafter, the sacrificial layers 206 in the channel regions 210C are selectively removed to release the channel layers 208 as the channel members (including upper channel members 2080U1, 2080U2, lower channel members 2080L1, and 2080L2) and nanostructures (including nanostructures 2080N1 and 2080N2). In the illustrated embodiments, the upper channel members 2080U1 and 2080U2 are in direct contact with the top source/drain features 248; the lower channel members 2080L1 and 2080L2 are in direct contact with the bottom source/drain features 230; and the nanostructures 2080N1, 2080N2 and the middle dielectric layer 226M are in direct contact with the bottom CESL 232. The selective removal of the sacrificial layers 206 may be implemented by a selective dry etch, a selective wet etch, or other selective etch processes. In some embodiments, the selective wet etching includes an APM etch (e.g., ammonia hydroxide-hydrogen peroxide-water mixture). The removal of the sacrificial layers 206 (e.g., sacrificial layers 206U1 and 206U2) of the top portion 204T forms gate openings 258a, and the removal of the sacrificial layers 206 (e.g., sacrificial layers 206L1, 206L2, and 206L3) of the bottom portion 204B forms gate openings 258b.

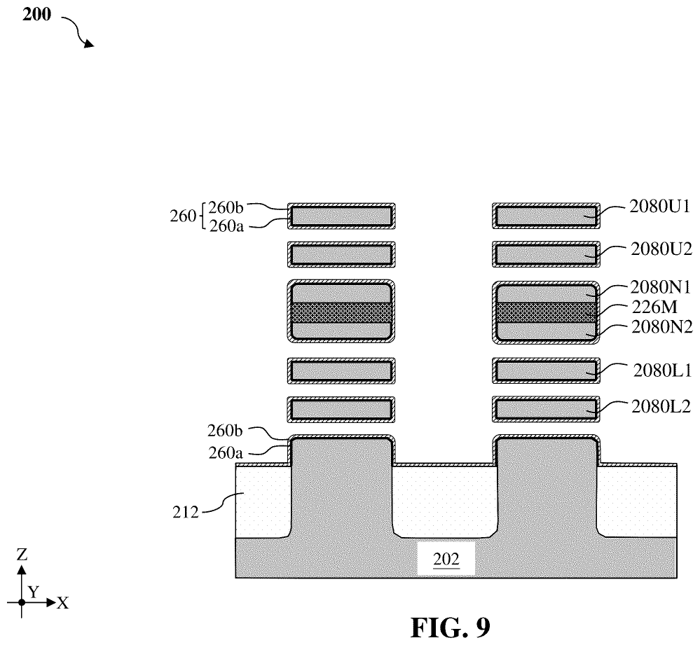

Referring to FIGS. 2 and 9, method 100 includes a block 112 where a gate dielectric layer 260 is formed over the intermediate structure 200, including in the gate trenches 256 and the gate openings 258a-258b. In this illustrated embodiment, the gate dielectric layer 260 includes an interfacial layer 260a formed on exposed surfaces of the channel members (e.g., 2080U1-2080U2, 2080L1-2080L2) and nanostructures (2080N1-2080N2). In an embodiment, the interfacial layer 260a is formed by, for example, thermal oxidization or chemical oxidization. In some other implementations, the interfacial layer 260a may be formed by ALD or CVD and thus is conformally formed over the intermediate structure 200, including on exposed surfaces of dielectric features (e.g., the isolation feature 212 and the middle dielectric layer 226M). In an embodiment, the interfacial layer 260s includes silicon oxide. The gate dielectric layer 260 also includes a high-k dielectric layer 260b over the interfacial layer 260a. The high-k dielectric layer 260b is deposited over the intermediate structure 200 using ALD, CVD, and/or other suitable methods. The high-k dielectric layer 260b is formed of high-k dielectric materials. As used and described herein, high-k dielectric materials include dielectric materials having a high dielectric constant, for example, greater than that of thermal silicon oxide (˜3.9). The high-k dielectric layer 260b may include hafnium oxide. Alternatively, the high-k dielectric layer 260b may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material.

Referring to FIGS. 2 and 10, method 100 includes a block 114 where a dipole layer 262 is conformally deposited over the gate dielectric layer 260. In this embodiment, the dipole layer 262 is a p dipole film. As used herein, a p dipole film generally refers to a dielectric film having a metal element that, when diffusing into a gate dielectric layer, can induce a dipole tending to lower a threshold voltage of the to-be-formed p-type transistor (e.g., a p-type lower multi-gate transistor). In some embodiments, the dipole layer 262 may be formed of hafnium oxide, lanthanum oxide, gallium oxide, zinc oxide, or aluminum oxide and may be deposited using atomic layer deposition (ALD). In one embodiment, the dipole layer 262 may be formed of gallium oxide. In the present embodiments, after the depositing of the dipole layer 262, the gate trenches 258 and gate openings 260a-260b are still partially filled.

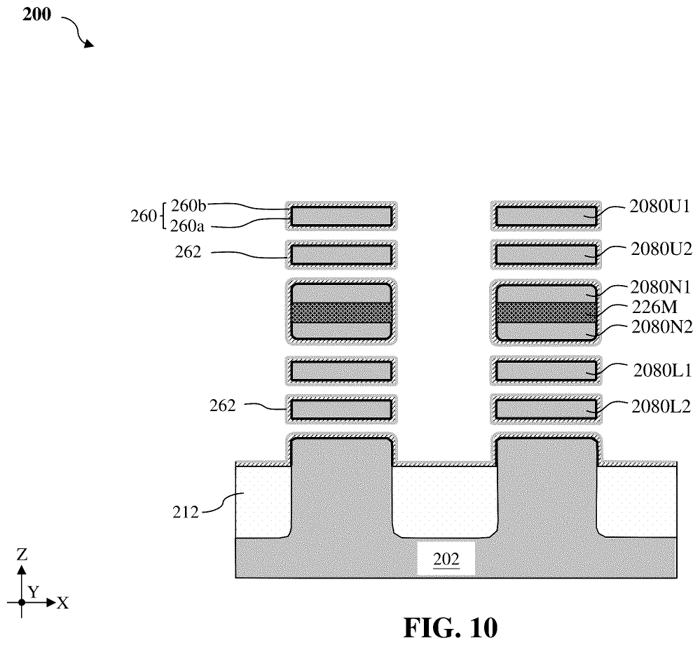

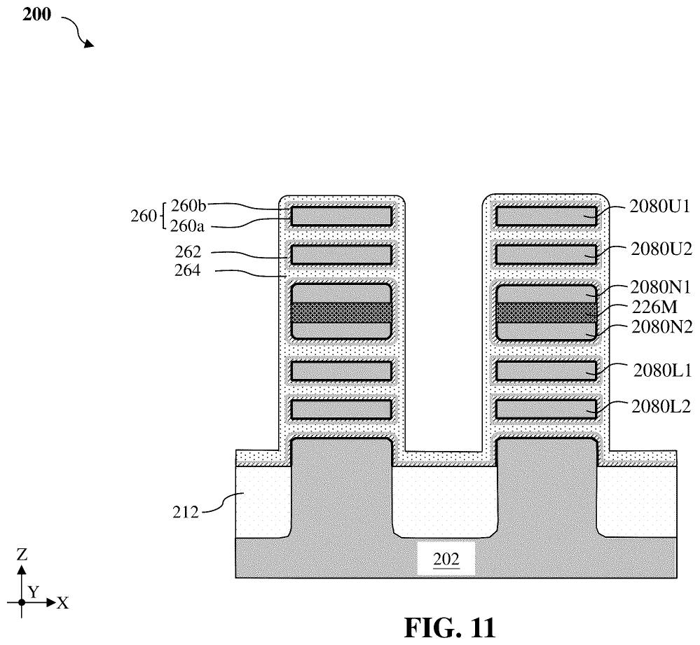

Referring to FIGS. 2 and 11, method 100 includes a block 116 where a pattern layer 264 is formed over the dipole layer 262. The pattern layer 264 is deposited over the intermediate structure 200 to cover the dipole layer 262. The pattern layer 264 may be formed by ALD, CVD, other suitable process, or a combination thereof. In some embodiments, the pattern layer 264 is formed by a spin-on deposition process or a CVD process. A composition of the pattern layer 264 is different than compositions of the dipole layer 262 and the high-k dielectric layers 260b to enable selective removal/etching thereof. In some embodiments, the pattern layer 264 is a dielectric material that includes silicon and oxygen, carbon, hydrogen, nitrogen, or a combination thereof. For example, the pattern layer 264 may be a silicon oxide layer or a silicon oxycarbide layer. In another embodiment, the pattern layer 264 includes aluminum oxide. A combination of the gate dielectric layer 260, the dipole layer 262 and the pattern layer 264 substantially fill the gate openings 258a-258b. The pattern layer 264 will provide protection to the dipole layer 262 and the high-k dielectric layer 260a during subsequent processes (e.g., operations at block 126).

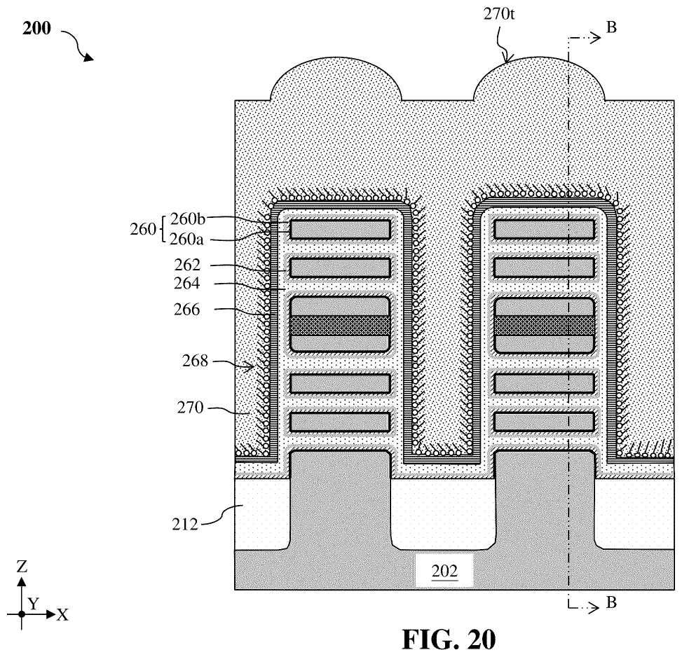

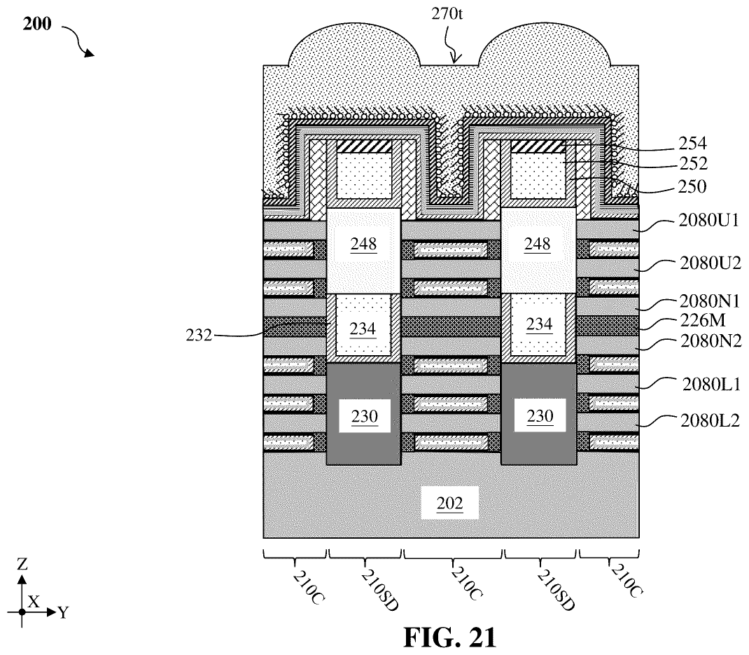

Referring to FIGS. 2 and 12, method 100 includes a block 118 where a barrier layer 266 is formed over the pattern layer 264. The barrier layer 266 is conformally deposited over the pattern layer 264 to have a generally uniform thickness over the top surface of the intermediate structure 200. As will be described later, in subsequent processes (e.g., operations at blocks 122, 124, 126), an oxide-based dummy layer 270 (shown in FIGS. 20-21) will be formed and then etched back to facilitate separate threshold voltage tunings for the upper multi-gate device and lower multi-gate device. Since the dummy layer 270 and the pattern layer 264 both may be formed of oxide layers, forming the barrier layer 266 having a different material to cover the pattern layer 264 may keep the integrity of the pattern layer 264 during the etch back process of the oxide-based dummy layer 270. That is, an etch selectivity between the oxide-based dummy layer 270 and the barrier layer 266 is higher than an etch selectivity between the oxide-based dummy layer 270 and the pattern layer 264. In an embodiment, the barrier layer 266 is formed of titanium nitride (TiN) and may be deposited using atomic layer deposition (ALD). In an embodiment, a thickness of the barrier layer 266 is between about 0.5 nm and about 5 nm. If the thickness of the barrier layer 266 is greater than about 5 nm, portions of the barrier layer 266 may occupy too much room of the gate trenches 256 or even merge together, adversely affecting or preventing the satisfactory formation of subsequent layers in some areas (e.g., in the gate trenches 256); and if the thickness of the barrier layer 266 is less than about 0.5 nm, during subsequent etch back process of the dummy layer 270, the barrier layer 266 may not be thick enough to undergo the etch back process to provide satisfactory protection for the pattern layer 264.

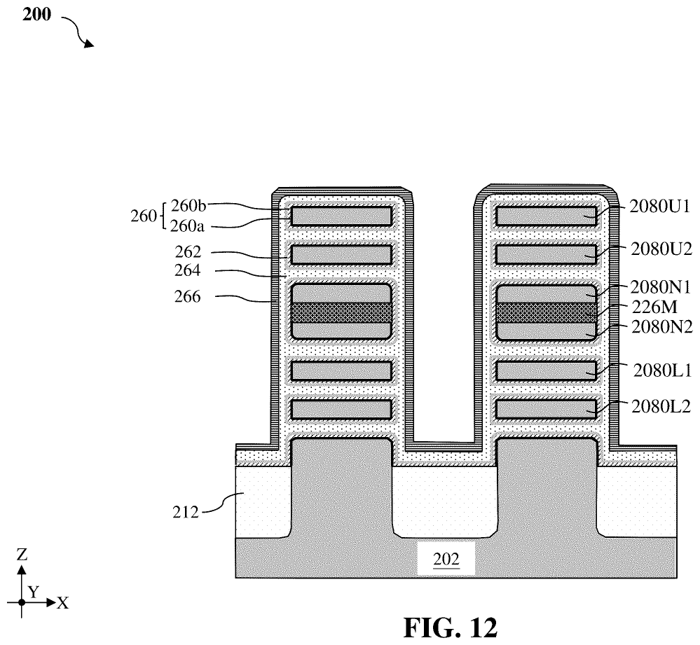

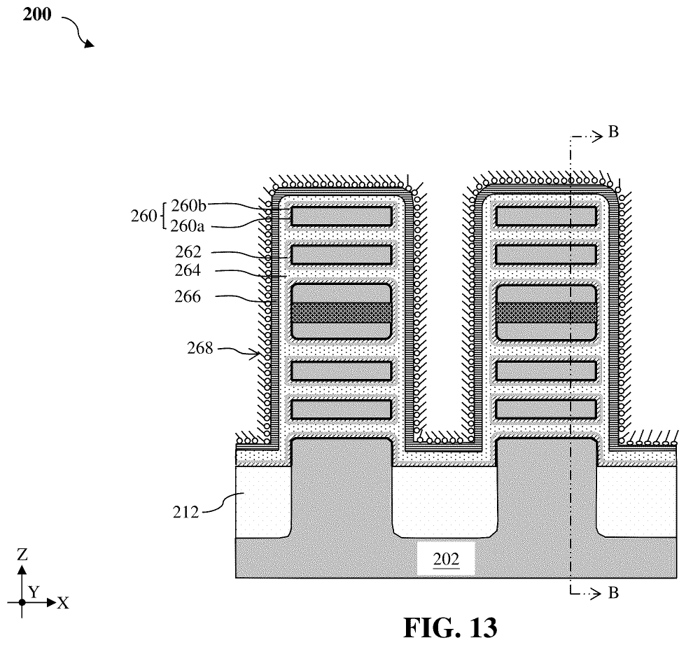

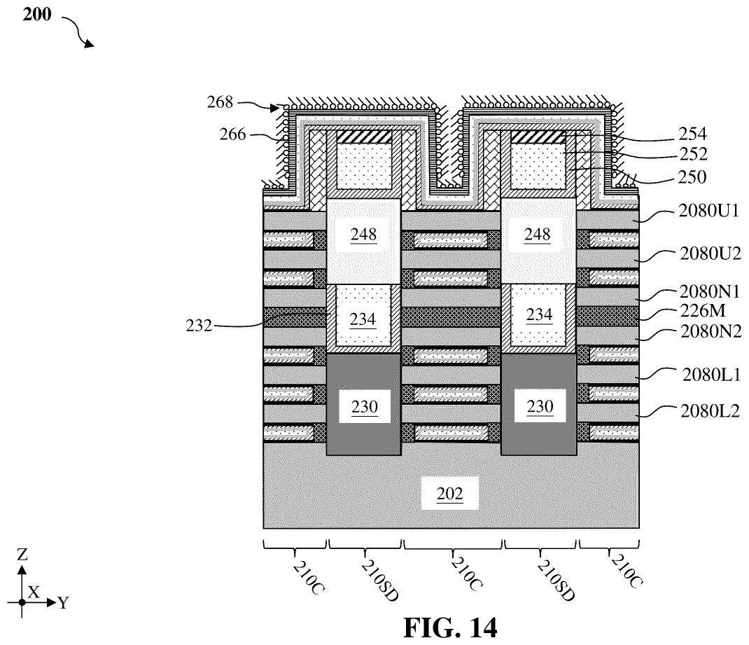

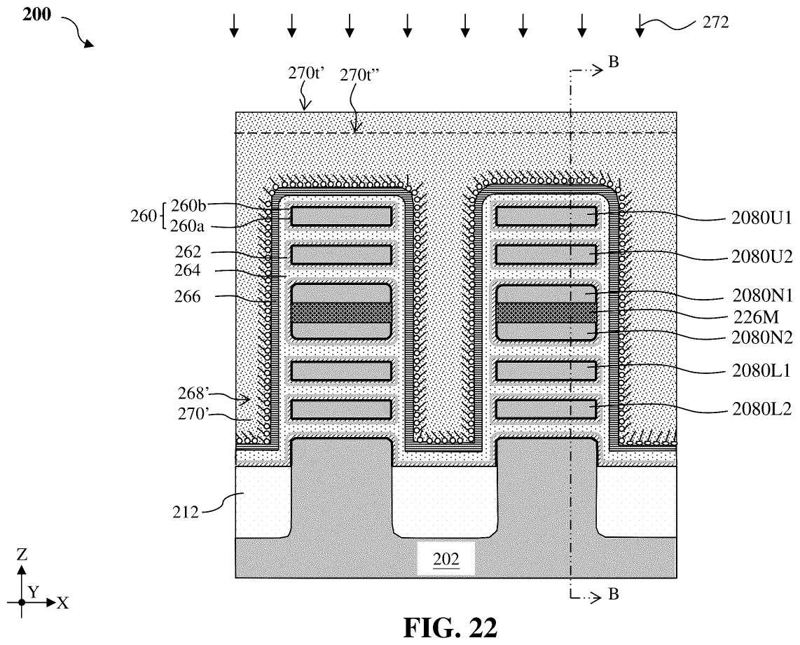

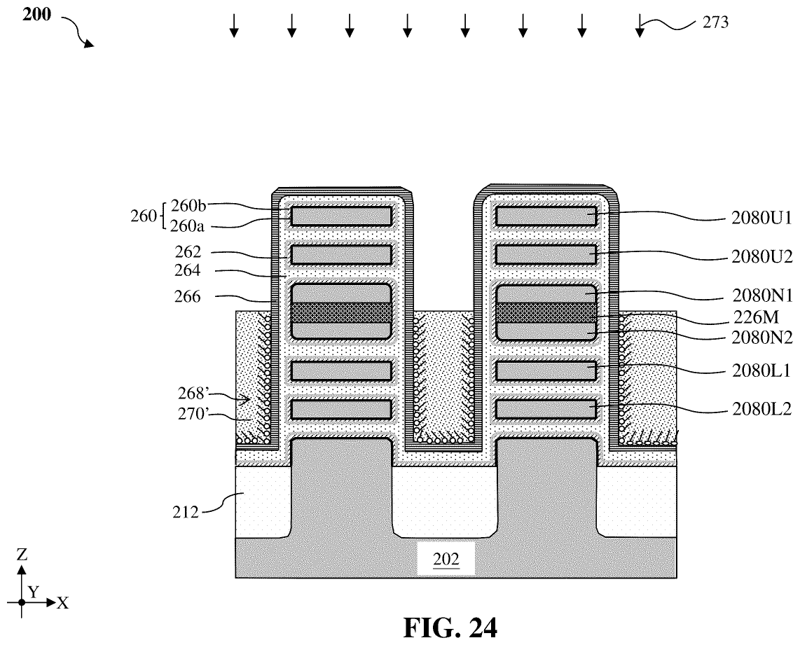

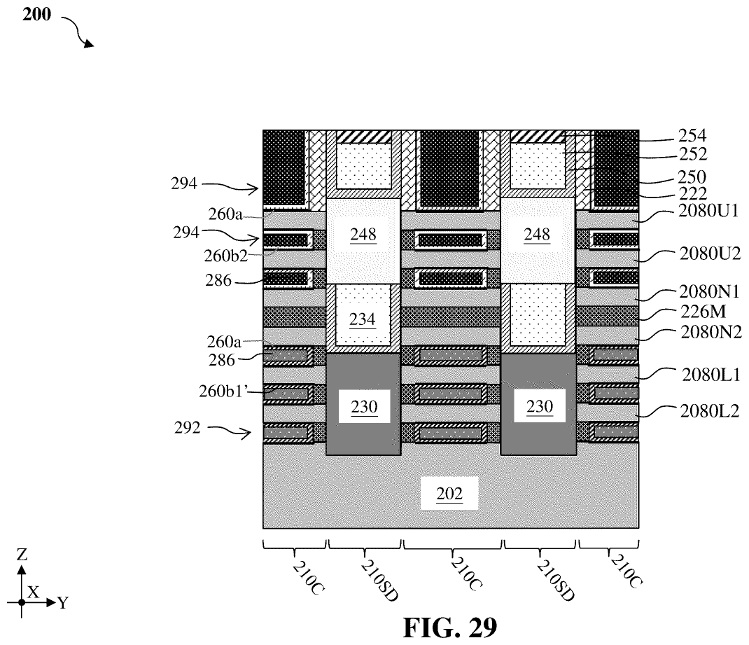

Referring to FIGS. 2 and 13-14, method 100 includes a block 120 where a self-assembled monolayer (SAM) 268 is formed on the barrier layer 266. FIG. 14 depicts a fragmentary cross-sectional view of the intermediate structure 200 taken along line B-B shown in FIG. 13. In some technologies, after forming the barrier layer 266, the oxide-based dummy layer 270 is formed on the barrier layer 266 and then planarized and etched back. However, the planarization process (e.g., planarization process 272 shown in FIG. 22) may remove a portion of the barrier layer 266 disposed directly over the gate spacers 222 and the hard mask 254. If this portion of the barrier layer 266 is removed during the planarization process, portions of the pattern layer 264, the dipole layer 262, and the gate dielectric layer 260, which are formed of oxide layers and previously covered by the removed portion of the barrier layer, may be removed during the etch back (e.g., the first etching process 273 described with reference to FIG. 24) of the oxide-based dummy layer 270. As a result, etchant of the subsequent etching process (e.g., the first etching process 273) may induce damage to the CESL 250, the hard mask 254 and the gate spacers 222 that can function as isolation between to-be-formed gate structure (e.g., top gate structure 294 shown in FIG. 29) and source/drain contacts adjacent to the gate structure. The unwanted damage to those isolation features may disadvantageously affect process window for forming gate structures and source/drain contacts, increase parasitic capacitance, and even lead to reliability issue.

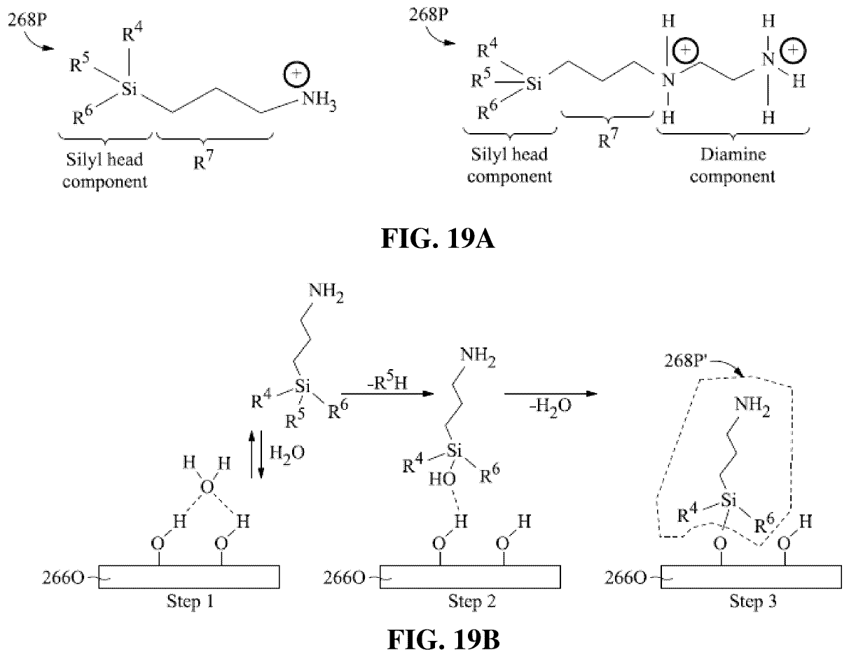

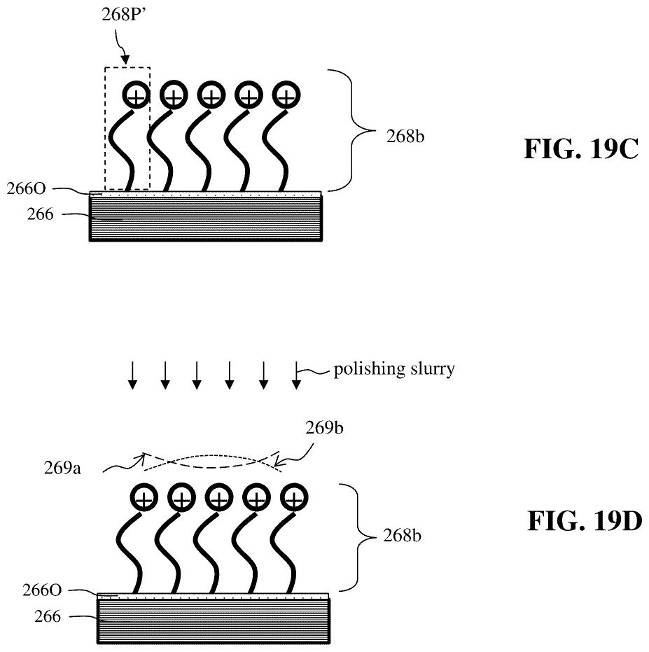

In this illustrated embodiment, a self-assembled monolayer (SAM) 268 is conformally formed on the barrier layer 266 to protect the barrier layer 266 from being damaged during the planarization process 272. Deposition processes for forming the barrier layer 266 and the SAM 268 may be performed in-situ. In an exemplary process, the formation of the barrier layer 266 is conducted in a process chamber, where the process chamber is prepared for a first deposition process for forming the barrier layer 266. After performing the first deposition process, the intermediate structure 200, which now includes the barrier layer 266, stays in the same process chamber that is then prepared for a second deposition process for forming the SAM 268. In another embodiment, the deposition processes for forming the barrier layer 266 and the SAM 268 are performed ex-situ. In an exemplary process, the formation of the barrier layer 266 is conducted in a first process chamber, where the first process chamber is prepared for the first deposition process for forming the barrier layer 266. After performing the first deposition process, the intermediate structure 200, which now includes the barrier layer 266, is transferred to a second process chamber, where the second process chamber is prepared for the second deposition process for forming the SAM 268. During the transfer process between the first process chamber and the second process chamber, a top surface of the barrier layer 266 may be partially oxidized, leading to an oxide-containing layer (e.g., the oxide-containing layer 2660 shown in FIGS. 19B-19D).

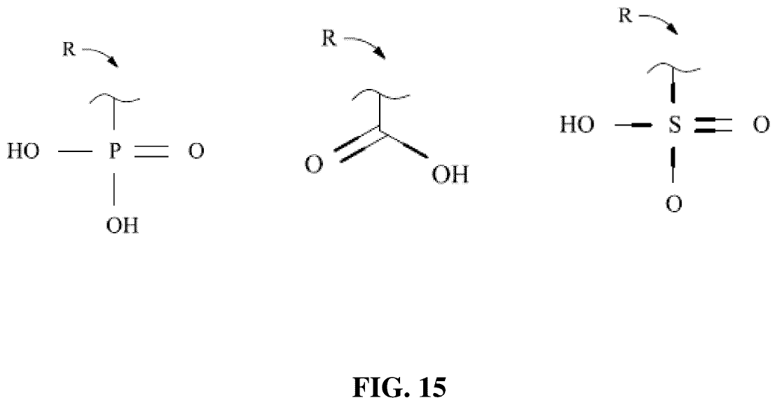

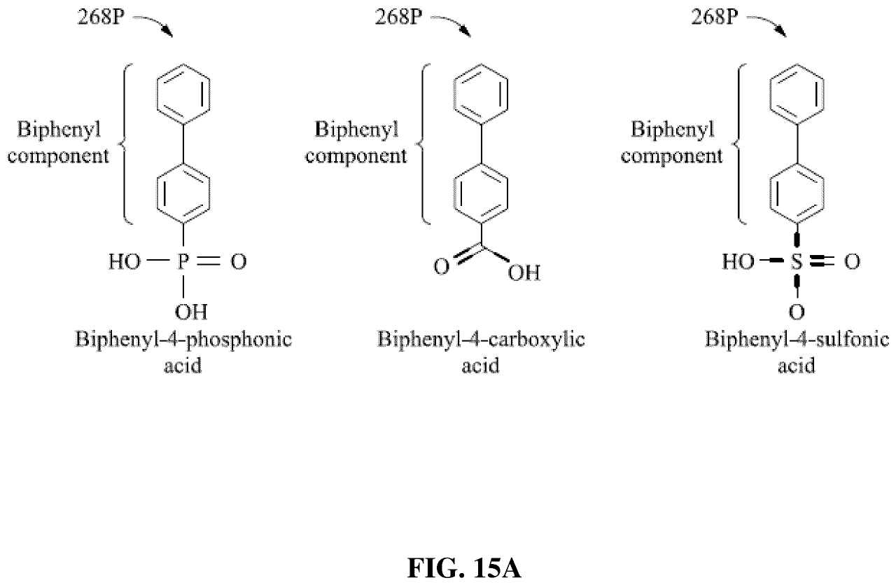

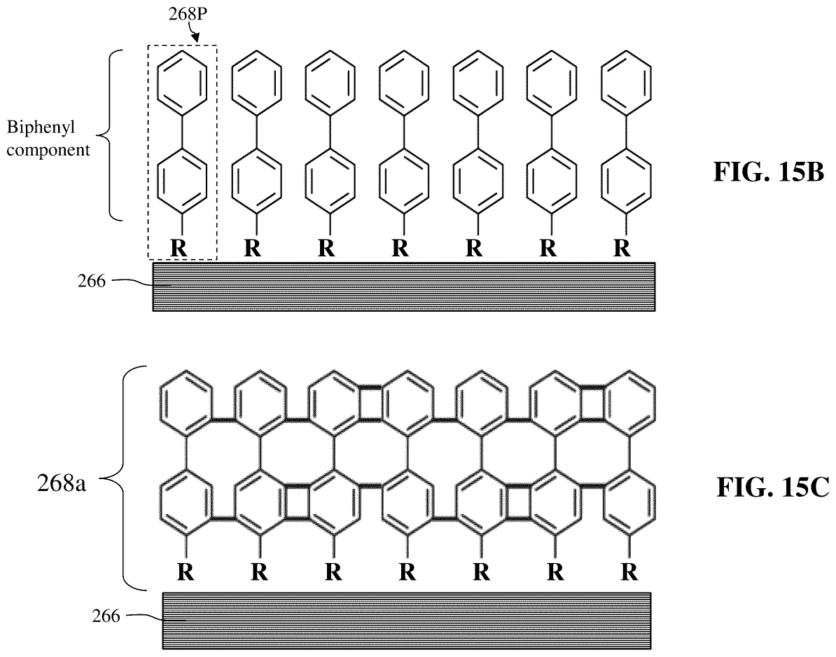

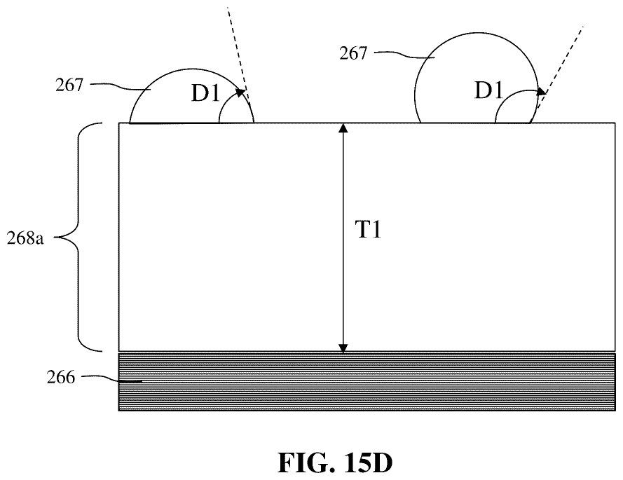

In this disclosure, two exemplary types of SAM 268 for providing protection to the barrier layer 266 during the planarization process 272 will be described. More specifically, a first type SAM 268a will be described in detail with reference to FIGS. 15 and 15A-18B, and a second type SAM 268b will be described in detail with reference to FIGS. 19A-19D.

With reference to FIGS. 15-18B, in some embodiments, forming the SAM 268 includes depositing SAM precursors 268P (shown in FIGS. 15C, 16A, 17A) over the barrier layer 266 to form a monolayer. The SAM precursor 268P may be polymerized (e.g., cross-linked) to form the first type SAM 268a. In some embodiments, the first type SAM 268a includes a monolayer of cross-linked SAM precursors 268P. Before depositing the SAM precursors 268P to form the first type SAM 268a, a cleaning process may be performed to remove the oxide-containing layer 2660 (e.g., a native oxide, such as titanium oxide) from the barrier layer 266. The cleaning process may use any suitable solution, such as diluted hydrogen fluoride (HF).

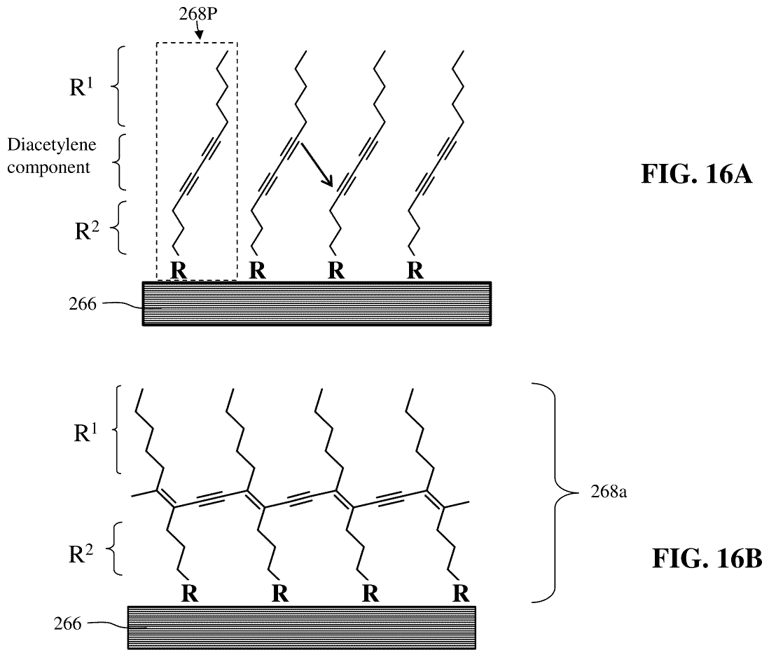

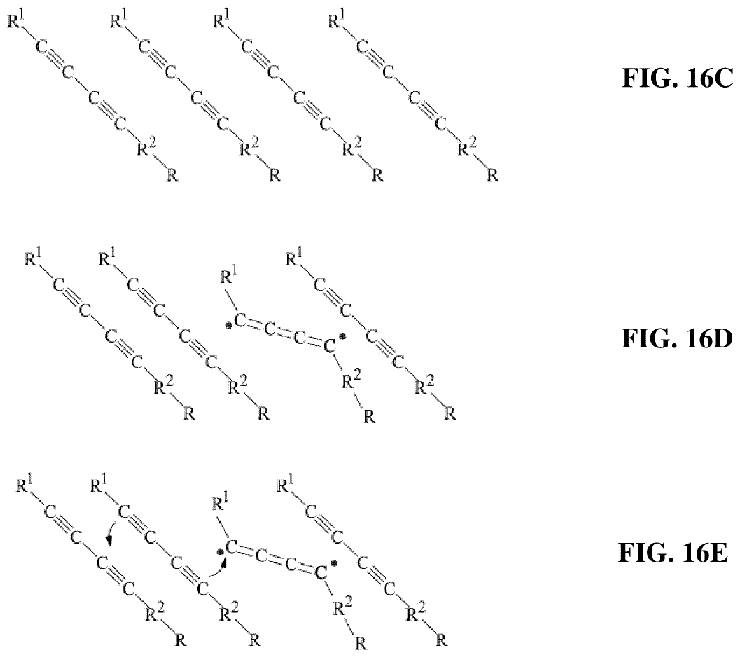

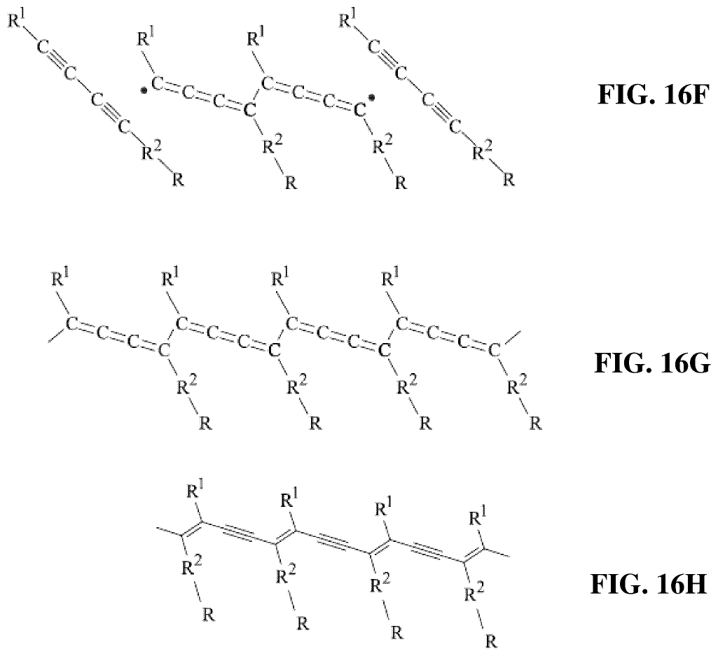

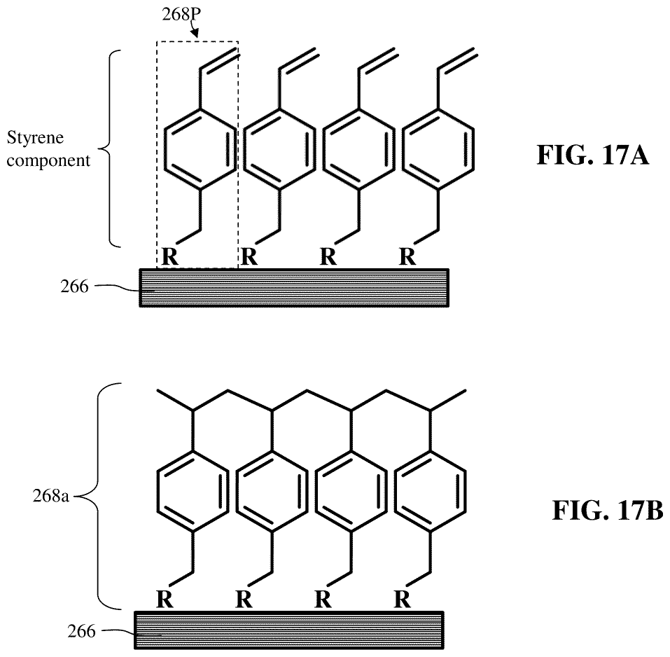

The SAM precursor 268P for forming the first type SAM 268a may include an acid head group R and a tail group connected together. In some embodiments, the acid head group R includes a phosphonic acid group (—PO₃H₂ group), a carboxyl group, or a sulfo group, combinations thereof, as depicted in FIG. 15. In some embodiments, the tail group includes a benzene component, a benzyl component, a biphenyl component (shown in FIG. 15A), a diacetylene component (shown in FIG. 16A), a styrene component (shown in FIG. 17A), a carbon-carbon double bond (C═C) component, a diene component, or a combination thereof. In some embodiments, unsaturated carbon-carbon bonds in the neighboring tail groups may cross-link one-by-one, thus polymerizing the SAM precursors 268P to form the first type SAM 268a. Cross-linking herein refers to forming of a chemical bond between different chains of atoms (e.g., neighboring SAM precursors 268P). The tail group may further include one or more alkyl component having 1 to 18 carbons, one or more alkylene component having 1 to 18 carbons, or a combination thereof.

FIGS. 15A-15D depict a first example of the first type SAM 268a. With reference to FIG. 15A, some examples of the SAM precursors 268P include a biphenyl component bonded to the acid head group (e.g., the phosphonic acid group, carboxyl group, or sulfo group) are provided. With reference to FIG. 15B, a number of the SAM precursors 268P including the biphenyl components may be deposited over the barrier layer 266. In some embodiments, the acid head group R binds with (or is adsorbed to) the barrier layer 266 by electrostatic force or covalent bond. In some embodiments, the acid head group R binds with TiN in the barrier layer 266 by electrostatic force. In some other embodiments, the acid head group R binds with Ti as an anion (in other words, losing an active proton). In some embodiments, the anion form of the acid head group coordinately bond the Ti atoms of TiN. As depicted, the acid head groups R of the number of the SAM precursors 268P may be arranged along a surface of the barrier layer 266, the tail groups may extend away from the surface of the barrier layer 266, and the SAM precursors 268P are self-aligned by electrostatic force or covalent bond to form a monolayer.

With reference to FIGS. 15C-15D, after depositing the number of the SAM precursors 268P, certain polymerization conditions (e.g., an energy source and/or a polymerization initiator) may be applied to the SAM precursors 268P to form the first type SAM 268a. A first polymerization condition (e.g., an electron beam) may stimulate the SAM precursors 268P, thereby cross-linking neighboring biphenyl components of the SAM precursors 268P to form the first type SAM 268a. Examples of the first polymerization condition may include an electron irradiation (e.g., an electron beam irradiation) at about 30 eV to about 70 eV, X-rays at about 10 eV to about 100 eV, an ion beam (e.g., helium ion beam (HIM)) at about 20 keV to about 50 keV, or an extreme UV (EUV) at about 80 eV to about 110 eV. Due to its cross-linked structure, the first type SAM 268a has improved mechanical stability and thermal stability compared to the SAM precursors 268P. For example, the first type SAM 268a has an increased mechanical integrity in a CMP process than the SAM precursors 268P, thus improving protection to the barrier layer 266. For example, the first type SAM 268a has a thermal stable temperature of about 600° C. to about 800° C., alternatively about 700° C. to about 800° C. The first type SAM 268a remains thermally stable below the thermal stable temperature. The thermal stable temperature of the first type SAM 268a is higher than that of the SAM precursors 268P. By adjusting parameters (e.g., voltage, power) of the first polymerization condition, the amount of the cross-linking bonds may be tuned, thus mechanical stability and thermal stability of the first type SAM 268a may be tuned. For example, increasing the voltage of the electron beam irradiation may result in more cross-linking bonds, and the mechanical property and stability of the first type SAM 268a may be increased.

The first type SAM 268a described with reference to FIGS. 15A-15C may have a thickness T1 (shown in FIG. 15D) of about 0.5 nm to about 2 nm. The first type SAM 268a may have a density of about 4 to about 10 molecules/nm². The density refers to number of the SAM precursor 268P per area of the first type SAM 268a. In some embodiments, the first type SAM 268a has a contact angle D1 of about 80 degree to about 130 degree as depicted. Contact angle herein refers to an angle established between an edge of the perimeter of a water drop (e.g., a water drop 267) and the surface (e.g., surface of the first type SAM 268a) it rests on. The contact angle may be measured in a contact angle measurement. The contact angle of the first type SAM 268a may be greater than that of the SAM precursors 268P, indicating that the first type SAM 268a has a lower surface energy and increased repellent to an aqueous slurry (e.g., a CMP slurry).

FIGS. 16A-16H depict a second example of the first type SAM 268a. More specifically, FIGS. 16A-16H illustrate diagrams of forming the first type SAM 268a from the SAM precursors 268P including diacetylene components. With reference to FIG. 16A, a number of the SAM precursors 268P including the diacetylene components may be deposited over the barrier layer 266. In the depicted embodiment, the SAM precursor 268P includes the acid head group R as described above, a group R², a diacetylene component, and a group R¹ in sequence. In some embodiments, both groups R¹ and R² include an alkyl component, having one to eighteen carbon atoms. For example, R¹ is a C1-C18 alkyl group, and R² is a C1-C18 alkylene component. Binding of the acid head group R to the barrier layer 266 and arrangement and alignment of the SAM precursors 268P may be similar to those described above with reference to FIG. 15B.

With reference to FIG. 16B, a second polymerization condition may stimulate the SAM precursors 268P, thereby cross-linking neighboring diacetylene components of the SAM precursors 268P to form the first type SAM 268a. Examples of the second polymerization condition may include an UV source (e.g., having a power of about 2 W to about 8 W and a wavelength of about 200 nm to about 300 nm) under air atmosphere and a temperature of about 5 degree C. to about 40 degree C., and/or an energy source having a power density of about 0.5 mW/cm² to about 2 mW/cm² at the SAM precursors 268P. The first type SAM 268a formed from the SAM precursors 268P including diacetylene components may similarly possess improved properties (e.g., mechanical stability, thermal stability, density, contact angle), have similar dimensions (e.g., thickness), with benefits similar to those described above for the first type SAM 268a formed from the SAM precursors 268P including biphenyl components.

FIGS. 16C-16H illustrate steps of cross-linking the neighboring diacetylene components. Referring to FIGS. 16C-16D, under the second polymerization condition (e.g., the UV source), the diacetylene component within SAM precursors 268P undergoes an internal 1,4-addition reaction. In this reaction, each alkyne groups of the stimulated diacetylene component are transformed into a C═C double bond with two reactive radicals on its respective ends. Because two of these reactive radicals are immediately adjacent to each other, an additional bond is formed therebetween. Accordingly, the original single bond connecting the two alkyne groups are transformed into a double bond. Meanwhile, the two remaining radicals remote to each other may attack adjacent diacetylene group of neighboring SAM precursor 268P (shown in FIG. 16E). This results in cross-linking between adjacent diacetylene components (shown in FIG. 16F). Because these reactions are radical in nature, they may propagate into other precursor 268P one-by-one (shown in FIG. 16G) to form an interconnected structure. Subsequently, rearrangement may occur to form a conjugated ene-yne polymeric chain illustrated in FIG. 16H. The cross-linked SAM precursors 268P together form the first type SAM 268a represented by FIG. 16B.

FIGS. 17A-17B depict a third example of the first type SAM 268a. More specifically, FIGS. 17A-17B illustrate the formation of the first type SAM 268a from the SAM precursors 268P that include styrene components. With reference to FIG. 17A, a number of the SAM precursors 268P including the styrene components may be deposited over the barrier layer 266. In the depicted embodiment, the SAM precursor 268P includes the acid head group R as described above and the styrene component connected to the acid head group R. Binding of the acid head group R to the barrier layer 266 and arrangement and alignment of the SAM precursors 268P may be similar to those described above with reference to FIG. 15B.

With reference to FIG. 17B, a third polymerization condition may stimulate the SAM precursors 268P, thereby cross-linking neighboring styrene components of the SAM precursors 268P to form the first type SAM 268a. Examples of the third polymerization condition may include immersing the intermediate structure 200 in an aqueous solution of an initiator (e.g., azo initiator) at a temperature of about 45 degree C. to about 110 degree C., or irradiating the monolayer of the SAM precursors 268P with a green laser having a wavelength of about 480 nm to about 570 nm. The green laser may further be used for detecting or observing the SAM 268. The power of the green laser for polymerization and for observation may be about 50 mW to about 500 mW and distributed over a spot having about 0.5 mm to about 5 mm in diameter. The SAM 268 formed from the SAM precursors 268P including styrene components may have similar properties (e.g., mechanical stability, thermal stability, density, contact angle), dimensions (e.g., thickness), and benefits as those described above for the SAM 268 formed from the SAM precursors 268P including biphenyl components.

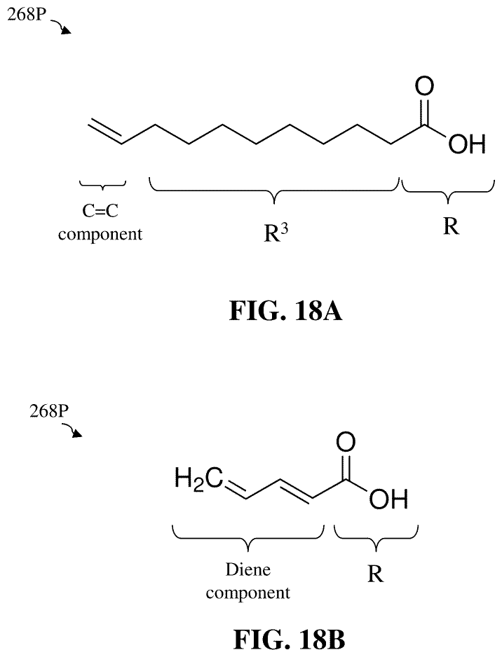

FIGS. 18A-18B illustrate additional examples of the SAM precursors 268P for forming the first type SAM 268a. In some embodiments, the SAM precursor 268P includes the acid head group R (e.g., a carboxyl group as in FIG. 18A) as described above, a group R³, and a C═C component in sequence. In some embodiments, R³ may include a C1-C18 alkylene component. In some embodiments, the C═C components of neighboring SAM precursors 268P cross-link to form the first type SAM 268a using similar method as described above. In some embodiments, the SAM precursor 268P includes the acid head group R (e.g., a carboxyl group as in FIG. 18B) as described above and a diene component. The diene component may include a 1,3-diene component as depicted. In some embodiments, at least one of the C═C bonds in the diene components of neighboring SAM precursors 268P cross-link to form the first type SAM 268a using similar method as described above. In some embodiments, the cross-linking occurs in a 1,2-addition manner. In some other embodiments, the cross-linking occurs in a 1,4-addition manner.

Now referring to FIGS. 19A-19D, which describe the second type SAM 268b and an exemplary method of forming the second type SAM 268b in detail. Forming the second type SAM 268b includes forming an oxide-containing layer 2660 on the barrier layer 266. As described above, in some embodiments, formation of the barrier layer 266 and the second type SAM 268b may be performed ex-situ, and the oxide-containing layer 2660 is formed during the transfer process between the first process chamber and the second process chamber. In some other embodiments, the forming of the barrier layer 266 and the second type SAM 268b are performed in-situ, and the oxide-containing layer 2660 may be formed by performing an oxidation process using a suitable oxidizer, such as ozone.

After forming the oxide-containing layer 2660, the SAM precursors 268P and water are deposited over the barrier layer 266. In some embodiments, water is deposited before depositing the SAM precursors 268P. In some other embodiments, the SAM precursors 268P and water are mixed and then deposited. In some embodiments, the SAM precursors 268P include silylalkylamine, silylalkyldiamine, or a combination thereof. FIG. 19A provides examples of the silylalkylamine and the silylalkyldiamine. In some embodiments, the silylalkylamine includes a silyl head component (SiR⁴R⁵R⁶), a group R⁷, and an amine group (—NH₂) in sequence. The amine group may be protonated to become —NH₃ with a positive charge. The groups R⁴, R⁵, and R⁶ may each be independently selected from —OC₂H₅, —OCH₃, and chlorine (—Cl). The group R⁷ may include a C1-C18 alkylene component. In some embodiments, the silylalkyldiamine includes the silyl head component, the group R⁷, and a diamine component in sequence. The diamine component includes two amine groups. The two amine groups may be connected by a C1-C6 alkylene component. In some embodiments, one or both of the amine groups are protonated.

With reference to FIG. 19B, after depositing the SAM precursors 268P and water over the oxide-containing layer 2660, a reaction takes place to bond the SAM precursors 268P to the oxide-containing layer 2660. The reaction may be a surface reaction. In some embodiments, the reaction may be a spontaneous reaction. In some embodiments, interactions between the oxide-containing layer 2660 and water form surface hydroxy groups on the surface of the oxide-containing layer 2660. At step 1, when water is introduced to the oxide-containing layer 2660, hydrogen bonds are formed between the surface hydroxy groups and the water molecules. At step 2, the hydrogen-bonded surface water may attack the SAM precursors 268P with its oxygen lone pair. For example, the oxygen lone pair may attack the silicon atom of the silyl head on the SAM precursors 268P, replacing one of the groups R⁴, R⁵, and R⁶ with a hydroxyl group. This interaction brings the silyl head to close proximity of the surface. At step 3, oxygen of the surface hydroxy group may attack the silyl silicon due to its proximity, forming a Si—O bond therebetween, and releases a water molecule at the same time. Accordingly, the substituted SAM precursors 268P is bonded to the oxide-containing layer 2660 through the Si—O bond. The remaining portion of the SAM precursors 268P in the dashed region may be referred to as reacted SAM precursors 268P′. As described, the reacted SAM precursors 268P′ may be bonded to the surface oxygen atoms on the oxide-containing layer 2660. The amine group(s) of the reacted SAM precursors 268P′ may further be protonated to have positive charge(s). The positive charge(s) may be at an end of the reacted SAM precursors 268P′ away from the silicon atom, and directing away from the surface of the oxide-containing layer 2660.

As represented by FIG. 19C, a number of the reacted SAM precursors 268P′ are bonded to the oxide-containing layer 2660 as described above and form a monolayer with positive charges. The positive charges are away from the oxide-containing layer 2660, and the reacted SAM precursors 268P′ are arranged one-by-one along the surface of the oxide-containing layer 2660. The reacted SAM precursors 268P′ may be self-aligned by electrostatic force or covalent bond to form the monolayer. The number of the reacted SAM precursors 268P′ on the oxide-containing layer 2660 may collectively form the second type SAM 268b.

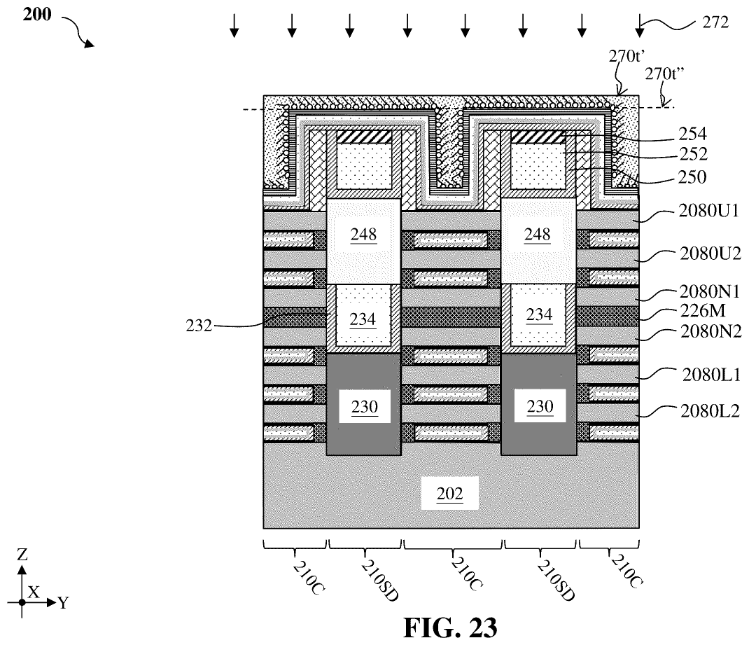

FIG. 19D explains the advantage of forming the second type SAM 268b over the barrier layer 266. During a planarization (e.g., chemical mechanical polishing (CMP)) process (e.g., the planarization process 272 shown in FIGS. 22-23), when a polishing slurry (e.g., a CMP slurry) is applied to the second type SAM 268b, the second type SAM 268b may have a repulsion (e.g., an electric repulsion) to the polishing slurry because of the positive charges. In some embodiments, the polishing slurry includes positively charged components and is repulsed by the second type SAM 268b. A first dashed line 269a indicates a profile of a bottom surface of the polishing slurry applied to, for example, the barrier layer 266 or the oxide-containing layer 2660, and a second dashed line 269b indicates of a bottom surface of the polishing slurry applied to the second type SAM 268b. Due to the existence of the positive charges of the second type SAM 268b, the repulsion between the polishing slurry and the second type SAM 268b may lead to a reduced extent of abrasion of the barrier layer 266 during the planarization process 272. In some embodiments, the barrier layer 266 may be protected from being abrased during the planarization process 272. The second type SAM 268b may have similar properties (e.g., mechanical stability, thermal stability, density, contact angle), dimensions (e.g., thickness), and benefits as those described above for the first type SAM 268a formed from the SAM precursors 268P including biphenyl components. The first type SAM 268a and the second type SAM 268b may be collectively or independently referred to as the SAM 268.

Referring to FIGS. 2 and 20-21, method 100 includes a block 122 where a dummy layer 270 is formed over the SAM 268. FIG. 21 depicts a fragmentary cross-sectional view of the intermediate structure 200 taken along line B-B shown in FIG. 20. In some embodiments, the dummy layer 270 may include materials such as tetraethylorthosilicate (TEOS) oxide, silicon oxide, and/or other suitable dielectric materials. In some embodiments, the dummy layer 270 may include silicon (Si), oxygen (O), and carbon (C). In an embodiment, the dummy layer 270 is formed of SiOC. The dummy layer 270 may be deposited using flowable CVD (FCVD), CVD, ALD, plasma-enhanced chemical vapor deposition (PECVD) or other suitable deposition technique. As shown in FIGS. 20-21, the dummy layer 270 is disposed over the barrier layer 266 and the SAM 268 and is above than a topmost surface of the SAM 268. After the depositing process, a top surface 270t of the dummy layer 270 is non-planar. For example, as illustrated by FIG. 20, a portion of the top surface 270t directly over the channel members in the channel regions 210C is above a portion of the top surface 270t directly over the isolation feature 212; and, as illustrated by FIG. 21, the portion of the top surface 270t directly over the channel regions 210C is under a portion of the top surface 270t directly over the source/drain regions 210SD.

Referring to FIGS. 2 and 22-23, method 100 includes a block 124 where a planarization process 272 is performed to the dummy layer 270. FIG. 23 depicts a fragmentary cross-sectional view of the intermediate structure 200 taken along line B-B shown in FIG. 22. To effectively reducing etching duration of the etching process (e.g., the first etching process 273) and precisely control a height of the recessed dummy layer 270 and thus control the boundary of gate dielectric layers of the lower multi-gate device and the upper multi-gate device, the planarization process 272 is performed to the dummy layer 270 to provide the dummy layer 270 a substantially planar top surface. The planarization process 272 is configured to substantially removes the portion of the dummy layer 270 disposed directly over the gate spacers 222 and the hard mask 254. Due to the existence of the SAM 268 (e.g., either the first type SAM 268a or the second type SAM 268b), abrasion of the barrier layer 266 may be substantially reduced or even eliminated. In an embodiment, after the performing of the planarization process 272, a top surface 270t′ of the dummy layer 270 is above a topmost surface of the barrier layer 266. In another embodiment, the SAM 268 may also function as an end point for the planarization process 272, and the planarization process 272 stops upon the removal of the portion of the SAM 268 directly over the gate spacers 222 and the hard mask 254. That is, upon completion of the planarization process 272, as indicated by the dashed line, a top surface 270t″ of the dummy layer 270 may be substantially coplanar with a topmost surface of the barrier layer 266. Upon completion of the planarization process 272, the intermediate structure 200 has a substantially planar top surface that is either coplanar with the top surface 270t′ or coplanar with the top surface 270t″. As illustrated by FIG. 22, the top surface 270t′ and the top surface 270t″ are above a topmost surface of the channel member 2080U1.

Referring to FIGS. 2 and 24, method 100 includes a block 126 where the dummy layer 270 and the SAM 268 are etched back. A first etching process 273 is performed to reduce a height of the dummy layer 270. In this illustrated embodiment, the first etching process 273 removes upper portions of the dummy layer 270 and the SAM 268 without substantially etching the barrier layer 266, the pattern layer 264, the dipole layer 262, and the gate dielectric layer 260 thereunder. Due to the existences of the barrier layer 266, the pattern layer 264 thereunder will not be damaged during the first etching process 273. The dummy layer 270 after the performing of the first etching process 273 is referred to as the dummy layer 270′, and the SAM 268 after the performing of the first etching process 273 is referred to as the SAM 268′. Duration of the first etching process 273 is controlled such that, upon completion of the first etching process 273, the upper channel members 2080U1-2080U2, the nanostructure 2080N1, and a portion of the middle dielectric layer 226M rise above a top surface of the dummy layer 270′. Top surfaces of the dummy layer 270′ and the SAM 268′ may be substantially coplanar and disposed between top and bottom surfaces of the middle dielectric layer 226M. The first etching process 273 may be an anisotropic dry etch that uses argon (Ar), oxygen (O₂), helium (He), hydrogen (H₂), hydrogen fluoride (HF), ammonia (NH₃), a plasma thereof, or a combination thereof. In an embodiment, etchant of the first etching process 273 includes a combination of ammonia and hydrogen fluoride. After performing the first etching process 273, as represented by FIG. 24, surfaces of an upper portion of the barrier layer 266 are exposed. In some embodiments, after performing the first etching process 273, a clean process is performed to remove residues (e.g., residues from the SAM 268 or byproducts of the first etching process 273) from the exposed surfaces of the barrier layer 266. The clean process may include a plasma process containing hydrogen radical.

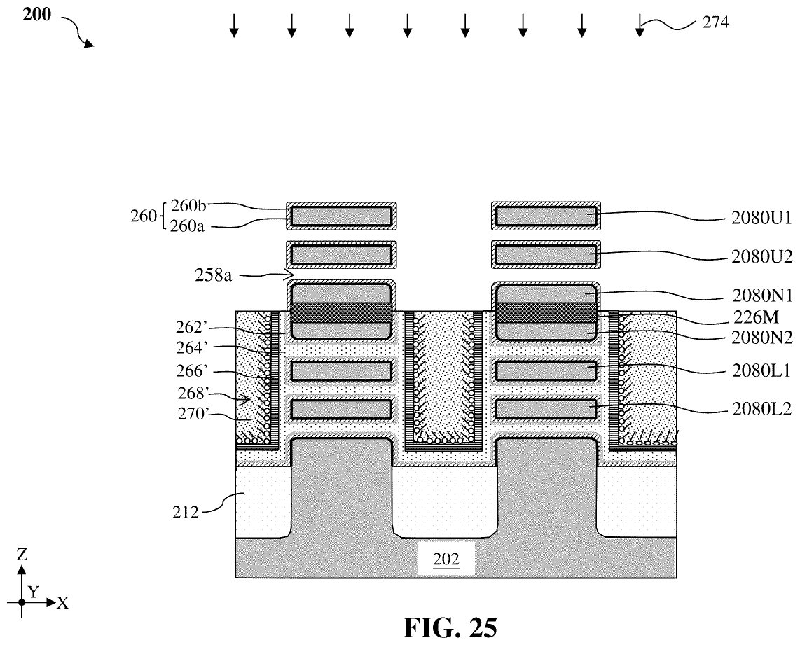

Referring to FIGS. 2 and 25, method 100 includes a block 128 where upper portions of the barrier layer 266, the pattern layer 264, and the dipole layer 262 not covered by the dummy layer 270′ are removed. As represented by FIG. 25, after the etch back of the dummy layer 270, surfaces of the upper portion of the barrier layer 266 over the upper channel members 2080U1-2080U2, the nanostructure 2080N1, and the portion of the middle dielectric layer 226M that rise above the top surface of the dummy layer 270′ is exposed. A second etching process 274 is then performed to remove the upper portion of the barrier layer 266 and portions of the pattern layer 264 and the dipole layer 262 previously covered by the upper portion of the barrier layer 266 to expose an upper portion of the gate dielectric layer 260 disposed over the dummy layer 270′. In some embodiments, the second etching process 274 may include one or more steps configured to remove different materials. For example, a first one of the steps of the second etching process 274 may selectively remove the upper portion of the barrier layer 266 and/or the pattern layer 264, and a second one of the steps of the second etching process 274 may selectively remove the upper portion of the dipole layer 262 without substantially etching the high-k dielectric layer 260b and may include an isotropic wet etch process that uses hydrochloric acid (HCl), RCA SC-1 (ammonia, hydrogen peroxide and water), RCA SC-2 (hydrochloric acid, hydrogen peroxide and water), or a combination thereof. The barrier layer 266, the pattern layer 264, and the dipole layer 262 after the performing of the second etching process 274 may be referred to as the barrier layer 266′, the pattern layer 264′, and the dipole layer 262′, respectively. That is, while using the dummy layer 270′ as an etch mask, the second etching process 274 is performed to pattern the dipole layer 262, thereby forming the dipole layer 262′. As illustrated by FIG. 25, the dipole layer 262′ extends over the portion of the gate dielectric layer 260 adjacent to the lower channel members 2080L1-2080L2, the nanostructure 2080N2, and a lower portion of the middle dielectric layer 226M under the top surface of the dummy layer 270′.

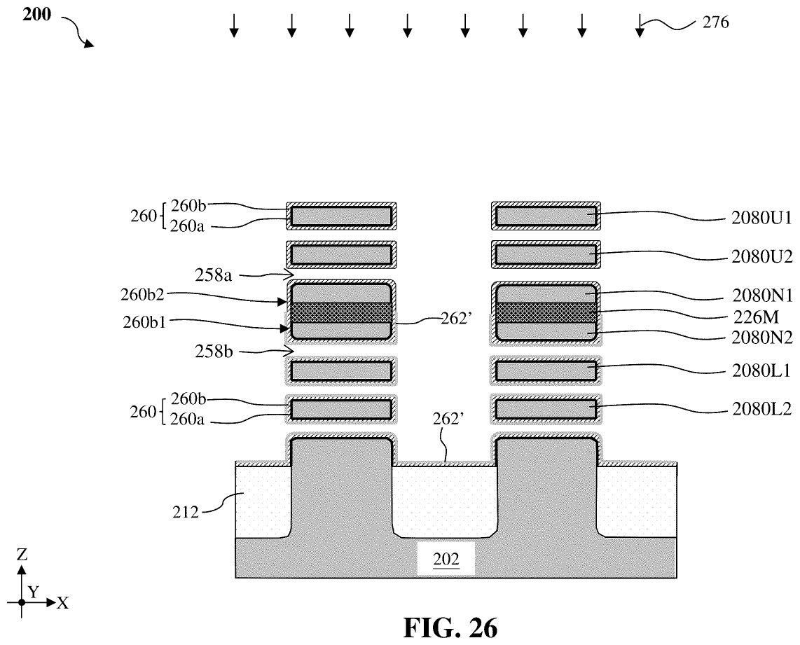

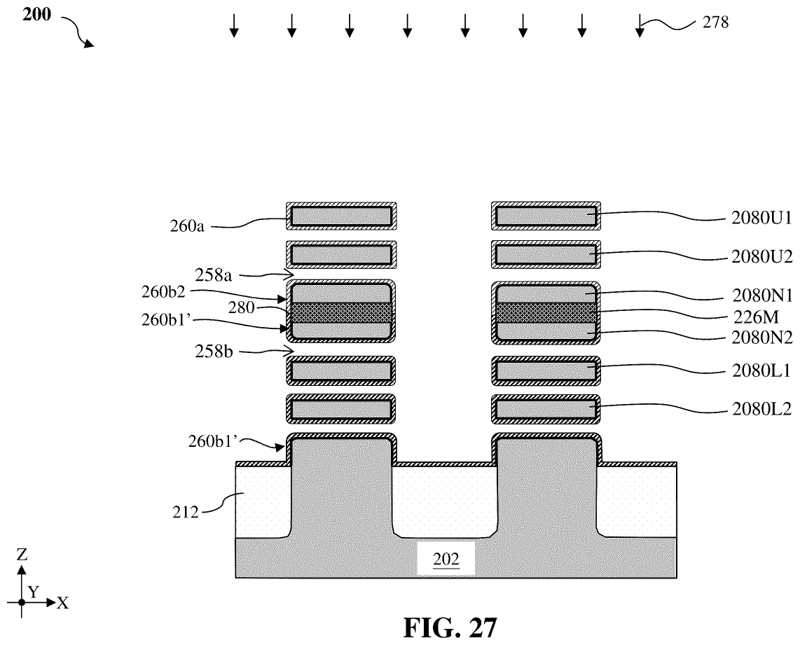

Referring to FIGS. 2 and 26, method 100 includes a block 130 where the dummy layer 270′, the SAM 268′, the barrier layer 266′, the pattern layer 264′ are removed. After patterning the dipole layer 262 to form the dipole layer 262′, a third etching process 276 is performed to selectively remove the dummy layer 270′, the SAM 268′, the barrier layer 266′, the pattern layer 264′ without substantially etching the dipole layer 262′. The third etching process 276 may include one or more etch steps configured to remove different compositions. For example, a first etch step may be configured to selectively remove the dummy layer 270′ and the SAM 268′, a second etch step may be configured to selectively remove the barrier layer 266′, and a third etch step is configured to selectively remove the pattern layer 264′. After the preforming of the third etching process 276, the dipole layer 262′ is exposed. In some embodiments, during and/or after performing the third etching process 276, a clean process may be performed to remove residues (e.g., residues from the SAM 268′ or byproducts of the third etching process 276) from the exposed surfaces of the dipole layer 262′. As illustrated by FIG. 26, a portion 260b1 of the high-k dielectric layer 260b disposed under the middle dielectric layer 226M is covered by the dipole layer 262′, a portion 260b2 of the high-k dielectric layer 260b disposed over the middle dielectric layer 226M is not covered by the dipole layer 262′. The portion 260b1 of the high-k dielectric layer 260b may be referred to as the high-k dielectric layer 260b1, and the portion 260b2 of the high-k dielectric layer 260b may be referred to as the high-k dielectric layer 260b2. At this point, the high-k dielectric layer 260b1 and the high-k dielectric layer 260b2 may have a same composition. In this illustrated embodiment, a topmost surface of the dipole layer 262′ is above a bottom surface of the middle dielectric layer 226M and under a top surface of the middle dielectric layer 226M. In some other embodiment, the topmost surface of the dipole layer 262′ may be coplanar with the bottom surface of the middle dielectric layer 226M or the top surface of the middle dielectric layer 226M.

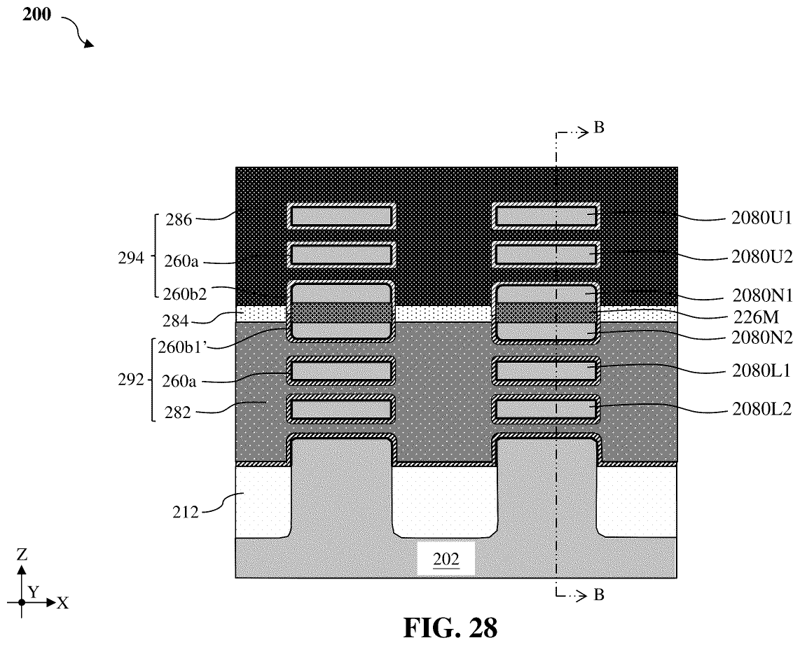

Referring to FIGS. 2 and 27, method 100 includes a block 132 where a drive-in process 278 is performed. The drive-in process 278 causes a dipole dopant species (e.g., hafnium, lanthanum, gallium, zinc, aluminum) in the dipole layer 262′ to diffuse into the high-k dielectric layer 260b1 or to an interface between the interfacial layer 260a and the high-k dielectric layer 260b1. That is, the drive-in process 278 drives in the dipole dopant species into the high-k dielectric layer 260b1 or to an interface between the interfacial layer 260a and the high-k dielectric layer 260b1. The drive-in process 278 may be a thermal drive-in process that includes rapid thermal annealing (RTA), millisecond annealing (MSA), microsecond annealing (μSA), or other suitable annealing processes. The high-k dielectric layer 260b1 after the performing of the drive-in process 278 may be referred to as the high-k dielectric layer 260b1′. The high-k dielectric layer 260b1′ includes the dipole dopant species. In some embodiments, the dipole dopant species may diffuse into the portion of the interfacial layer 260a covered by the high-k dielectric layer 260b1. Because the high-k dielectric layer 260b2 is not in direct contact with the dipole layer 262′, the drive-in process 278 at block 132 does not result in any dipole dopant species diffusing into the high-k dielectric layer 260b2. A dashed line 280 is illustrated to represent the boundary between the high-k dielectric layer 260b1′ and the high-k dielectric layer 260b2. Although the illustrated dashed line 280 is above the bottom surface of the middle dielectric layer 226M and below the top surface of the middle dielectric layer 226M, in some other implementations, the dashed line 280 may be coplanar with the bottom surface of the middle dielectric layer 226M or the top surface of the middle dielectric layer 226M. After performing the drive-in process 278, as represented by FIG. 27, the dipole layer 262′ is selectively removed without substantially etching the high-k dielectric layer 260b1′. The dipole layer 262′ may be removed using a wet etch process that uses hydrochloric acid (HCl), RCA SC-1 (ammonia, hydrogen peroxide and water), RCA SC-2 (hydrochloric acid, hydrogen peroxide and water), or a combination thereof.

Referring to FIGS. 2 and 28-29, method 100 includes a block 134 where a first gate electrode 282 and a second gate electrode 286 are formed. FIG. 29 depicts a cross-sectional view of the intermediate structure 200 taken along line B-B as shown in FIG. 28. Operations at block 134 include formation of the first gate electrode 282 to wrap around the lower channel members 2080L1-2080L2, formation of an insulation layer 284 to electrically isolate the first gate electrode 282 from the to-be-deposited second gate electrode 286, and formation the second gate electrode 286. The first gate electrode 282 and the second gate electrode 286 may include titanium nitride (TiN), titanium aluminum (TiAl), molybdenum (Mo), or ruthenium (Ru). In some embodiments, despite the dipole engineering described above to provide different threshold voltages, compositions of the first gate electrode 282 and the second gate electrode 286 may still be different to further adjust the threshold voltages for the lower multi-gate device and the upper multi-gate device. For example, when the lower multi-gate device is a p-type transistor and the upper multi-gate device is an n-type transistor, the first gate electrode 282 may include a p-type work function layer, and the second gate electrode 286 may include an n-type work function layer. By way of example, the p-type work function layer may include titanium nitride (TiN), tantalum nitride (TaN), ruthenium (Ru), molybdenum (Mo), other p-type work function material, or combinations thereof, and the n-type work function layer may include titanium aluminum (TiAl), titanium aluminum carbide (TiAlC), tantalum aluminum (TaAl), tantalum aluminum carbide (TaAlC), titanium aluminum nitride (TiAlN), other n-type work function material, or combinations thereof. In some other embodiments, the dipole engineering described above determines the threshold voltage of the upper and lower multi-gate devices and the first gate electrode 282 and the second gate electrode 286 may have a same composition.

In an exemplary process, the first gate electrode 282 is deposited, using ALD or CVD, over the high-k dielectric layers 260b1′ and 260b2, including in the gate trenches 256 and gate openings 258a-258b. Then, the first gate electrode 282 is etched back using a suitable process, such as a dry etch process that includes a chlorine containing precursor (e.g., HCl, Cl₂, BCl₃) and a hydrocarbon (e.g., CH4, C₂H₆), until a top surface of the first gate electrode 282 is substantially coplanar with a bottom surface of the middle dielectric layer 226M. After the etching back, an insulation layer is deposited over the first gate electrode 282 and then etched back to form the insulation layer 284 on the first gate electrode 282. The insulation layer 284 may include a dielectric material, such as silicon oxycarbonitride or silicon oxycarbide. After that, the second gate electrode 286 is formed on the insulation layer 284 and in the gate trenches 256 and gate openings 258a. The first gate electrode 282, the high-k dielectric layer 260b1′, and the portion of the interfacial layer 260a disposed under the insulation layer 284 may be parts of a first gate structure 292 (or a “bottom gate structure 292”) formed in the gate openings 258b. The second gate electrode 286, the high-k dielectric layer 260b2, and the portion of the interfacial layer 260a disposed over the insulation layer 284 may be parts of a second gate structure 294 (or a “top gate structure 294”) formed in the gate trenches 256 and the gate openings 258a. The bottom gate structure 292 and/or the top gate structure 294 may also include a liner layer, a wetting layer, an adhesion layer, a metal alloy, or a metal silicide. The bottom gate structure 292 and/or the top gate structure 294 may also include a metal fill to reduce contact resistance. In some instance, the metal fill includes tungsten (W). The bottom gate structure 292, the bottom source/drain features 230, and the lower channel members 2080L1-2080L2 form a lower gate-all-around (GAA transistor) similar to the lower device 10L illustrated by FIG. 1. The top gate structure 294, the top source/drain features 248, and the upper channel members 2080U1-2080U2 form an upper gate-all-around (GAA transistor) similar to the upper device 10U illustrated by FIG. 1.

Method 100 also includes performing further processes to complete the fabrication of the semiconductor device 200. Such further processes may include forming silicide layers over the source/drain features and forming a multi-layer interconnect (MLI) structure over the intermediate structure 200. The MLI may include various interconnect features, such as vias and conductive lines, disposed in dielectric layers, such as etch-stop layers and ILD layers. In some embodiments, the vias are vertical interconnect features configured to interconnect device-level contacts, such as source/drain contacts formed over the source/drain features. Other processes may be further performed.

Although not intended to be limiting, one or more embodiments of the present disclosure provide many benefits to a semiconductor device and the formation thereof. For example, the present disclosure provides a mechanism for protecting a barrier layer from being abrased during a planarization process. Protecting the barrier layer may advantageously decrease parasitic capacitance and improve reliability of the semiconductor device.

The present disclosure provides for many different embodiments. Semiconductor structures and methods of fabrication thereof are disclosed herein. In one exemplary aspect, the present disclosure is directed to a method. The method includes forming a gate dielectric layer to wrap around a bottom channel member and a top channel member that is disposed over the bottom channel member, depositing a dipole layer over the gate dielectric layer, the dipole layer comprising a first portion around the top channel member and a second portion around the bottom channel member, forming a first dummy layer over the dipole layer, forming a self-assembled monolayer (SAM) on a top surface of the first dummy layer, depositing a second dummy layer over the SAM, a top surface of the second dummy layer being non-planar, performing a planarization process to the second dummy layer, after the performing of the planarization process, recessing the second dummy layer such that the top channel member is disposed above the top surface of the recessed second dummy layer and the bottom channel member is disposed below a top surface of the recessed second dummy layer, performing a first etching process to remove a portion of the first dummy layer and the first portion of the dipole layer to expose the gate dielectric layer around the top channel member, performing a second etching process to expose a sidewall surface of the second portion of the dipole layer, after the performing of the second etching process, performing a thermal drive-in process to drive a dipole dopant species from the second portion of the dipole layer into the gate dielectric layer around the bottom channel member, and selectively removing the dipole layer.

In some embodiments, the first dummy layer may include a first layer and a second layer on the first layer, and the first layer and the second layer have different compositions. In some embodiments, an etch selectivity between the second layer and the second dummy layer is greater than an etch selectivity between the first layer and the second dummy layer. In some embodiments, the first layer may include aluminum oxide. In some embodiments, the second layer may include titanium nitride. In some embodiments, after the performing of the planarization process, a topmost surface of the second dummy layer is above or coplanar with a topmost surface of the first dummy layer. In some embodiments, the performing of the planarization process further removes a portion of the SAM disposed on the topmost surface of the first dummy layer. In some embodiments, the recessing of the second dummy layer may include performing a third etching process, and etchant of the third etching process further selectively removes a portion of the SAM over the first portion of the dipole layer. In some embodiments, the method may also include, after the performing of the third etching process, performing a clean process remove residues from surfaces of the first dummy layer. In some embodiments, the method may also include forming a first gate electrode to wrap around the bottom channel member, depositing an insulation layer over the first gate electrode, and forming a second gate electrode to wrap around the top channel member.

In another exemplary aspect, the present disclosure is directed to a method. The method includes receiving an intermediate structure comprising a bottom nanostructure over a substrate, a top nanostructure over the bottom nanostructure, and an isolation layer disposed vertically between the bottom nanostructure and the top nanostructure, forming a gate dielectric layer over the substrate, the gate dielectric layer comprising a first portion wrapping around the bottom nanostructure and a second portion wrapping around the top nanostructure, depositing a dipole layer on the gate dielectric layer, after the depositing of the dipole layer, forming a pattern layer over the dipole layer, forming a self-assembled monolayer (SAM) over the pattern layer, forming a dummy layer on the SAM, planarizing the dummy layer, removing portions of the SAM and the dummy layer disposed over the isolation layer, removing portions of the pattern layer and the dipole layer over the isolation layer, removing remaining portions of the SAM, the dummy layer, and the pattern layer, thereby leaving a portion of the dipole layer on the first portion of the gate dielectric layer, and performing a treatment to drive a dipole dopant species from the portion of the dipole layer to the first portion of the gate dielectric layer.

In some embodiments, the forming of the SAM may include depositing a plurality of precursors over the pattern layer, and performing a treatment to the plurality of precursors to induce polymerization among the plurality of precursors, thereby forming the SAM. In some embodiments, each of the plurality of precursors may include a tail group and a head group, the head group comprises a phosphonic acid group (—PO₃H₂ group), a carboxyl group, or a sulfo group. In some embodiments, the method may also include forming a barrier layer between the pattern layer and the SAM, wherein an etch selectivity between the barrier layer and the dummy layer is greater than an etch selectivity between the pattern layer and the dummy layer. In some embodiments, the barrier layer may include titanium nitride. In some embodiments, the planarizing of the dummy layer further removes a portion of the SAM on the barrier layer, and upon completion of the planarizing, topmost surfaces of the dummy layer, the barrier layer, and the SAM are substantially coplanar. In some embodiments, the barrier layer has a substantially uniform thickness in a range between about 0.5 nm and about 5 nm.

In yet another exemplary aspect, the present disclosure is directed to a semiconductor device. The semiconductor device includes forming a titanium nitride layer over a substrate, forming a self-assembled monolayer (SAM) on the titanium nitride layer, forming a dummy oxide layer on the SAM, performing a planarization process to planarize the dummy oxide layer, wherein, a top surface of the planarized dummy oxide layer is substantially planar and above a topmost surface of the titanium nitride layer, after the performing of the planarization process, removing a portion of the planarized dummy oxide layer and a portion of the SAM, and after the removing of the portion of the planarized dummy oxide layer and the portion of the SAM, removing a portion of the titanium nitride layer not covered by the SAM.

In some embodiments, the forming of the self-assembled monolayer (SAM) may include depositing a plurality of precursors over the titanium nitride layer, and performing a treatment to the plurality of precursors to induce polymerization among the plurality of precursors. In some embodiments, each of the plurality of precursors may include head group and a tail group, the head group may include a phosphonic acid group (—PO₃H₂ group), a carboxyl group, or a sulfo group, and the tail group may include a benzene component, a benzyl component, a biphenyl component, a diacetylene component, a styrene component, a carbon-carbon double bond (C═C) component, or a diene component.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a gate dielectric layer to wrap around a bottom channel member and a top channel member that is disposed over the bottom channel member;
depositing a dipole layer over the gate dielectric layer, the dipole layer comprising a first portion around the top channel member and a second portion around the bottom channel member;
forming a first dummy layer over the dipole layer;
forming a self-assembled monolayer (SAM) on a top surface of the first dummy layer;
depositing a second dummy layer over the SAM, wherein a top surface of the second dummy layer is non-planar;
performing a planarization process to the second dummy layer;
after the performing of the planarization process, recessing the second dummy layer such that the top channel member is disposed above the top surface of the recessed second dummy layer and the bottom channel member is disposed below a top surface of the recessed second dummy layer;
performing a first etching process to remove a portion of the first dummy layer and the first portion of the dipole layer to expose the gate dielectric layer around the top channel member;
performing a second etching process to expose a sidewall surface of the second portion of the dipole layer;
after the performing of the second etching process, performing a thermal drive-in process to drive a dipole dopant species from the second portion of the dipole layer into the gate dielectric layer around the bottom channel member; and
selectively removing the dipole layer.

2. The method of claim 1, wherein the first dummy layer comprises a first layer and a second layer on the first layer, wherein the first layer and the second layer have different compositions.

3. The method of claim 2, wherein an etch selectivity between the second layer and the second dummy layer is greater than an etch selectivity between the first layer and the second dummy layer.

4. The method of claim 2, wherein the first layer comprises aluminum oxide.

5. The method of claim 2, wherein the second layer comprises titanium nitride.

6. The method of claim 1, wherein, after the performing of the planarization process, a topmost surface of the second dummy layer is above or coplanar with a topmost surface of the first dummy layer.

7. The method of claim 6, wherein the performing of the planarization process further removes a portion of the SAM disposed on the topmost surface of the first dummy layer.

8. The method of claim 1, wherein the recessing of the second dummy layer comprises performing a third etching process, and etchant of the third etching process further selectively removes a portion of the SAM over the first portion of the dipole layer.

9. The method of claim 8, further comprising:
after the performing of the third etching process, performing a clean process remove residues from surfaces of the first dummy layer.

10. The method of claim 1, further comprising:
forming a first gate electrode to wrap around the bottom channel member;
depositing an insulation layer over the first gate electrode; and
forming a second gate electrode to wrap around the top channel member.

11. A method, comprising:
receiving an intermediate structure comprising:
a bottom nanostructure over a substrate,
a top nanostructure over the bottom nanostructure, and
an isolation layer disposed vertically between the bottom nanostructure and the top nanostructure;
forming a gate dielectric layer over the substrate, the gate dielectric layer comprising a first portion wrapping around the bottom nanostructure and a second portion wrapping around the top nanostructure;
depositing a dipole layer on the gate dielectric layer;
after the depositing of the dipole layer, forming a pattern layer over the dipole layer;
forming a self-assembled monolayer (SAM) over the pattern layer;
forming a dummy layer on the SAM;
planarizing the dummy layer;
removing portions of the SAM and the dummy layer disposed over the isolation layer;
removing portions of the pattern layer and the dipole layer over the isolation layer;
removing remaining portions of the SAM, the dummy layer, and the pattern layer, thereby leaving a portion of the dipole layer on the first portion of the gate dielectric layer; and
performing a treatment to drive a dipole dopant species from the portion of the dipole layer to the first portion of the gate dielectric layer.

12. The method of claim 11, wherein the forming of the SAM comprises:
depositing a plurality of precursors over the pattern layer; and
performing a treatment to the plurality of precursors to induce polymerization among the plurality of precursors, thereby forming the SAM.

13. The method of claim 12, wherein each of the plurality of precursors comprises a tail group and a head group, the head group comprises a phosphonic acid group (—PO₃H₂ group), a carboxyl group, or a sulfo group.

14. The method of claim 11, further comprising:
forming a barrier layer between the pattern layer and the SAM, wherein an etch selectivity between the barrier layer and the dummy layer is greater than an etch selectivity between the pattern layer and the dummy layer.

15. The method of claim 14, wherein the barrier layer comprises titanium nitride.

16. The method of claim 14, wherein the planarizing of the dummy layer further removes a portion of the SAM on the barrier layer, and upon completion of the planarizing, topmost surfaces of the dummy layer, the barrier layer, and the SAM are substantially coplanar.

17. The method of claim 15, wherein the barrier layer has a substantially uniform thickness in a range between about 0.5 nm and about 5 nm.

18. A method, comprising:
forming a titanium nitride layer over a substrate;
forming a self-assembled monolayer (SAM) on the titanium nitride layer;
forming a dummy oxide layer on the SAM;
performing a planarization process to planarize the dummy oxide layer, wherein, a top surface of the planarized dummy oxide layer is substantially planar and above a topmost surface of the titanium nitride layer;
after the performing of the planarization process, removing a portion of the planarized dummy oxide layer and a portion of the SAM; and
after the removing of the portion of the planarized dummy oxide layer and the portion of the SAM, removing a portion of the titanium nitride layer not covered by the SAM.

19. The method of claim 18, wherein the forming of the self-assembled monolayer (SAM) comprises:
depositing a plurality of precursors over the titanium nitride layer; and
performing a treatment to the plurality of precursors to induce polymerization among the plurality of precursors.

20. The method of claim 19, wherein each of the plurality of precursors comprises head group and a tail group, the head group comprises a phosphonic acid group (—PO₃H₂ group), a carboxyl group, or a sulfo group, and the tail group comprises a benzene component, a benzyl component, a biphenyl component, a diacetylene component, a styrene component, a carbon-carbon double bond (C═C) component, or a diene component.
